(19) United States
(12) Patent Application Publication
(10) Pub. No.: US 2024/0242006 A1
(43) Pub. Date: Jul. 18, 2024

(54) System, Method, and Computer Program Product for Reducing Artifacts in Networked Simulations

(71) Applicant: Scott Alexander Stanczak, Franklin, TN (US)

(72) Inventor: Scott Alexander Stanczak, Franklin, TN (US)

(21) Appl. No.: 18/415,221

(22) Filed: Jan. 17, 2024

Related U.S. Application Data
(60) Provisional application No. 63/480,176, filed on Jan. 17, 2023.

(51) Int. Cl. G06F 30/20

(52) U.S. Cl. CPC G06F 30/20

(57) ABSTRACT

A system, method, and computer program product for reducing artifacts in networked simulations using reconciliation with a combined peer-to-peer and authoritative network architecture, comprising obtaining at least one input associated with an authoritative simulation state from a first client device of a plurality of client devices, the first client device executing a first simulation instance, associating a delayed processing penalty with the first client device, the delayed processing penalty providing a minimum acceptable duration that elapses between an initial instance associated with the at least one input by the first client device and a subsequent instance when generating the authoritative simulation state based on the at least one input of the first client device, routing simulation information to the plurality of client devices, the simulation information associated with the authoritative simulation state, and updating one or more simulation instances of the first client device with the simulation information.

### CROSS-REFERENCE TO RELATED APPLICATION

This application claims the benefit of U.S. Provisional Patent Application No. 63/480,176, filed Jan. 17, 2023, the disclosure of which is hereby incorporated by reference in its entirety.

### BACKGROUND

### 1. Field

This disclosure relates generally to a peer-assisted authoritative network architecture including, in some non-limiting embodiments or aspects, systems, methods, and computer program products for reducing artifacts in networked simulations providing reconciliation with a combined peer-to-peer and authoritative network architecture.

### 2. Technical Considerations

Computer networks (e.g., networks of connected computing devices) may utilize a central server that may execute and/or synchronize networked simulations (e.g., networked games, simulations and/or games executing on a network, etc.) based on inputs from trusted and/or untrusted sources, such as clients (e.g., client devices, user computing devices, etc.) connected to the central authority executing the networked simulation. In other cases, computer networks may be designed to include a peer-to-peer architecture. In some cases, when executing a networked simulation using a client device and/or a central authority, client devices in communication with the networked simulation may experience network artifacts.

Network artifacts may include simulation desynchronizations between members (e.g., between client devices, servers, network devices, and/or the like) of the network that the networked simulation is part of (e.g., an instance of a simulation executing on a central authority and an instance of the simulation executing on one or more clients connected to the network occurring within a networked simulation). For example, a network artifact on a client device (e.g., rendering on an output device of a client device, appearing on a client device, etc.) may include a rapid shift (e.g., a visual shift, etc.) of an object that is rendered on an output device (e.g., monitor, screen, etc.) of the client device, where the object may include a representation of position (e.g., a position based on coordinates, etc.) within a networked simulation. Network artifacts may arise in a computer network due to latency, such as, between a client device connected to the network and the central authority. In cases of a peer-to-peer architecture, network artifacts may arise due to latency between members (e.g., two client devices, etc.) of the same network. Network artifacts may also arise due to application logic (e.g., instructions and/or logic that is executed by a computing device while a networked simulation is executed, etc.).

Network artifacts that arise due to application logic may occur as a result of applying inputs (e.g., executing input commands, etc.) from client devices to a networked simulation (e.g., a simulation instance executing on the client device, etc.) instantaneously (e.g., client-side prediction). Applying inputs from client devices to a networked simulation instantly may improve the experience of a user (e.g., responsiveness of graphical outputs from the client device, for example, using a monitor device, etc.) of a client device executing a networked simulation. In order to reduce network artifacts that may result from the application of inputs from a client device instantaneously to a networked simulation (e.g., networked simulation systems, etc.), networked simulations may implement methods designed to retroactively process the inputs from the client device applied to the simulation.

However, in a network architecture using a central authority executing a networked simulation, some methods designed to retroactively process inputs at the central authority where the inputs from the client device are applied to a simulation instance on the client-side (e.g., on the client device) require the central authority to replicate the conditions of the simulation (e.g., state, simulation state, etc.) at the time the inputs were applied to the simulation instance on the client-side. The replication of conditions of the simulation by the central authority may further cause the occurrence of network artifacts that may negatively impact an experience of a user using a client device.

Additionally, some methods designed to retroactively process inputs (e.g., rollback, etc.) would require large amounts of computing resources if implemented at the central authority. The replication of conditions of the simulation by the central authority may execute inputs which had previously been executed by a simulation instance on a client device (e.g., past inputs, etc.). Applying (e.g., executing, etc.) inputs to the simulation instance operating on the central authority that had already been applied to a simulation instance executing on a client device may result in advantages for a first user using a first client device against a second user using a second client device (e.g., peeker's advantage, and/or the like). For example, the first user (e.g., operating on the first client device, etc.) may have previously applied inputs to the simulation instance operating on the first client device. The first client device may apply further inputs to the simulation instance on the first client device before the simulation instance operating on the central authority applies each of the previously applied inputs, generates outputs based on the previously applied inputs, and transmits the generated outputs to the second client device. This may not provide enough time to ensure the simulation instance operating on the second client device is updated according to the simulation instance operating on the central authority.

When using a peer-to-peer architecture to execute a networked simulation, the maximum number of client devices that may be connected via the computer network while still ensuring maximum integrity is two. Thus, as the number of client devices in a peer-to-peer network increases, the potential for malicious behavior also increases. This malicious behavior could manifest as intentional interference with the communication or input exchanges between different clients, conflicting and/or delayed inputs to each individual client device connected to the networked simulation, and/or conflicts or delays in the simulation process.

### SUMMARY

Accordingly, provided are improved systems, methods, and computer program products for reducing artifacts in networked simulations.

According to non-limiting embodiments or aspects, provided is a computer-implemented method for reducing artifacts in a networked simulation, comprising: obtaining, with at least one processor, at least one input associated with an authoritative simulation state from a first client device of a plurality of client devices, the first client device executing a first simulation instance; associating, with the at least one processor, a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and routing, with the at least one processor, simulation information to the plurality of client devices, the simulation information associated with the authoritative simulation state, wherein one or more simulation instances of the first client device of the plurality of client devices are updated with the simulation information.

In some non-limiting embodiments or aspects, communicating via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

In some non-limiting embodiments or aspects, updating a current simulation state of the first simulation instance of the one or more simulation instances based on the simulation information routed by the central authority to each client device of the plurality of client devices; or updating the current simulation state based on the at least one input transmitted by at least one of the client devices to an other client device of the plurality of client devices.

In some non-limiting embodiments or aspects, communicating the simulation information by a central authority to at least one client device of the plurality of client devices based on the at least one input received by the central authority from at least one other client device of the plurality of client devices.

In some non-limiting embodiments or aspects, executing a master simulation instance, the master simulation instance comprising a master simulation state, wherein the master simulation state provides a source of the authoritative simulation state, the authoritative simulation state comprising at least a subset of the master simulation state.

In some non-limiting embodiments or aspects, providing a reconciliation window, the reconciliation window including a duration of a network latency time that establishes a maximum latency time between the central authority and at least one client device of the plurality of client devices; and periodically updating the master simulation state of the master simulation instance based on a duration of the reconciliation window elapsing.

In some non-limiting embodiments or aspects, detecting one or more network characteristics related to a transmission duration in at least one communication from the first client device to a second client device; determining from the one or more network characteristics that the at least one communication arrived on time or that the communication from the first client device to the second client device, satisfies a first threshold value of transmission time; and in response to determining the one or more characteristics satisfies a first threshold value of transmission time, initiating a protective measure by terminating a connection between the first client device and the second client device.

In some non-limiting embodiments or aspects, determining contents of a communication between the first client device and a second client device; determining a second variation in the contents of the communication between the first client device and a second client device satisfies a first threshold value of variation in network latency; and in response to determining that a first variation in packet contents satisfies the first threshold value of variation in the network latency, initiating a protective measure by terminating a connection between the first client device and the second client device.

In some non-limiting embodiments or aspects, a central authority is configured to transmit a decryption key to the second client device, and further comprising: transmitting, by the first client device, an encrypted packet to the second client device of the plurality of client devices; transmitting, a corresponding decryption key to the second client device, wherein the decryption key is sent by a client device of the plurality of client devices or the central authority; and generating a first transmission time indicating when to transmit the decryption key from the central authority to the second client device of the plurality of client devices, the first transmission time based on subtracting a first duration from a second transmission time, wherein the first duration is based on a difference between a second duration and a third duration, wherein the first transmission time is determined by: v=t−(p−l) such that v is equal to the first transmission time, t is equal to the second transmission time, l is equal to the second duration, and p is equal to the third duration, wherein the second duration is based on a latency or distance between the first client device and the second client device, the third duration is based on the delayed processing penalty associated with the second client device.

According to non-limiting embodiments or aspects, provided is a system, comprising: a memory; and at least one processor coupled to the memory and configured to: obtain at least one input associated with an authoritative simulation state from a first client device of a plurality of client devices, the first client device executing a first simulation instance; associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and route simulation information to the plurality of client devices, the simulation information associated with the authoritative simulation state, wherein one or more simulation instances of the first client device of the plurality of client devices are updated with the simulation information.

In some non-limiting embodiments or aspects, the at least one processor is further configured to: communicate via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

In some non-limiting embodiments or aspects, the at least one processor is further configured to: update a current simulation state of the first simulation instance of the one or more simulation instances based on the simulation information routed by the central authority to each client device of the plurality of client devices; or update the current simulation state based on the at least one input transmitted by at least one of the client devices to another client device of the plurality of client devices.

In some non-limiting embodiments or aspects, the at least one processor is further configured to: communicate the simulation information by a central authority to at least one client device of the plurality of client devices based on the at least one input received by the central authority from at least one other client device of the plurality of client devices.

In some non-limiting embodiments or aspects, the at least one processor is further configured to: execute a master simulation instance, the master simulation instance comprising a master simulation state, wherein the master simulation state provides a source of the authoritative simulation state, the authoritative simulation state comprising at least a subset of the master simulation state.

In some non-limiting embodiments or aspects, the at least one processor is further configured to: provide a reconciliation window, the reconciliation window including a duration of a network latency time that establishes a maximum latency time between the central authority and at least one client device of the plurality of client devices; and periodically update the master simulation state of the master simulation instance based on the duration of the reconciliation window elapsing.

In some non-limiting embodiments or aspects, the at least one processor is further configured to: detect one or more network characteristics related to a network latency in at least one communication between the first client device and a second client device; determine from the one or more network characteristics that the at least one communication arrived on time or that a first variation between the first client device and the second client device satisfies a first threshold value of variation in the network latency; and in response to determining that the first variation of a network latency satisfies the first threshold value of variation in network latency, initiate a protective measure by terminating a connection between the first client device and the second client device.

In some non-limiting embodiments or aspects, the at least one processor is further configured to: determine contents of a communication between the first client device and a second client device; determine a second variation in the contents of the communication between the first client device and the second client device, satisfies a first threshold value of variation in a network latency; and in response to determining that a first variation in packet contents satisfies the first threshold value of variation in the network latency, initiate a protective measure by terminating a connection between the first client device and the second client device.

In some non-limiting embodiments or aspects, a central authority is configured to transmit a decryption key to the second client device, and the at least one processor is further configured to: transmit an encrypted packet to the second client device of the plurality of client devices; transmit a corresponding decryption key to the second client device, wherein the decryption key is sent by a client device of the plurality of client devices or the central authority; and generate a first transmission time indicating when to transmit the decryption key from the central authority to the second client device of the plurality of client devices, the first transmission time based on subtracting a first duration from a second transmission time, wherein the first duration is based on a difference between a second duration from a third duration, wherein the first transmission time is determined by: v=t−(p−l) such that v is equal to the first transmission time, t is equal to the second transmission time, l is equal to the second duration, and p is equal to the third duration, wherein the second duration is based on a latency or distance between the first client device and the second client device, the third duration is based on the delayed processing penalty associated with the second client device.

According to non-limiting embodiments or aspects, provided is a non-transitory computer-readable medium having instructions stored thereon that, when executed by at least one computing device, cause the at least one computing device to: obtain at least one input associated with an authoritative simulation state from a first client device of a plurality of client devices, the first client device executing a first simulation instance; associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and route simulation information to the plurality of client devices, the simulation information associated with the authoritative simulation state, wherein one or more simulation instances of the first client device of the plurality of client devices are updated with the simulation information.

Further non-limiting embodiments or aspects are set forth in the following numbered clauses:

Clause 1: A computer-implemented method for reducing artifacts in a networked simulation, comprising: obtaining, with the at least one processor, at least one input associated with an authoritative simulation state from a first client device of a plurality of client devices, the first client device executing a first simulation instance; associating, with the at least one processor, a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and routing, with the at least one processor, simulation information to the plurality of client devices, the simulation information associated with the authoritative simulation state, wherein one or more simulation instances of the first client device of the plurality of client devices are updated with the simulation information.

Clause 2. The computer-implemented method of clause 1, further comprising: communicating via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

Clause 3: The computer-implemented method of clauses 1 or 2, further comprising: updating a current simulation state of the first simulation instance of the one or more simulation instances based on the simulation information routed by the central authority to each client device of the plurality of client devices; or updating the current simulation state based on the at least one input transmitted by at least one of the client devices to an other client device of the plurality of client devices.

Clause 4: The computer-implemented method of clauses 1-3, further comprising: communicating the simulation information by a central authority to at least one client device of the plurality of client devices based on the at least one input received by the central authority from at least one other client device of the plurality of client devices.

Clause 5: The computer-implemented method of clauses 1-4, further comprising: executing a master simulation instance, the master simulation instance comprising a master simulation state, wherein the master simulation state provides a source of the authoritative simulation state, the authoritative simulation state comprising at least a subset of the master simulation state.

Clause 6: The computer-implemented method of clauses 1-5, further comprising: providing a reconciliation window, the reconciliation window including a duration of a network latency time that establishes a maximum latency time between the central authority and at least one client device of the plurality of client devices; and periodically updating the master simulation state of the master simulation instance based on a duration of the reconciliation window elapsing.

Clause 7: The computer-implemented method of clauses 1-6, further comprising: detecting one or more network characteristics related to a transmission duration in at least one communication from the first client device to a second client device; determining from the one or more network characteristics that the at least one communication arrived on time or that the communication from the first client device to the second client device, satisfies a first threshold value of transmission time; and in response to determining the one or more characteristics satisfies a first threshold value of transmission time, initiating a protective measure by terminating a connection between the first client device and the second client device.

Clause 8: The computer-implemented method of clauses 1-7, further comprising: determining contents of a communication between the first client device and a second client device; determining a second variation in the contents of the communication between the first client device and a second client device satisfies a first threshold value of variation in network latency; and in response to determining that a first variation in packet contents satisfies the first threshold value of variation in the network latency, initiating a protective measure by terminating a connection between the first client device and the second client device.

Clause 9: The computer-implemented method of clauses 1-8, wherein a central authority is configured to transmit a decryption key to the second client device, and further comprising: transmitting, by the first client device, an encrypted packet to the second client device of the plurality of client devices; transmitting, a corresponding decryption key to the second client device, wherein the decryption key is sent by a client device of the plurality of client devices or the central authority; and generating a first transmission time indicating when to transmit the decryption key from the central authority to the second client device of the plurality of client devices, the first transmission time based on subtracting a first duration from a second transmission time, wherein the first duration is based on a difference between a second duration and a third duration, wherein the first transmission time is determined by: v=t−(p−l) such that v is equal to the first transmission time, t is equal to the second transmission time, l is equal to the second duration, and p is equal to the third duration, wherein the second duration is based on a latency or distance between the first client device and the second client device, the third duration is based on the delayed processing penalty associated with the second client device.

Clause 10: The computer-implemented method of clauses 1-9, wherein the second transmission time is based on a time the first client device transmits the encrypted packet to the second client device; and the central authority knows an encryption key that will be used by a specific client at a specific time for communicating with a specific peer.

Clause 11: A system, comprising: a memory; and at least one processor coupled to the memory and configured to: obtain at least one input associated with an authoritative simulation state from a first client device of a plurality of client devices, the first client device executing a first simulation instance; associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and route simulation information to the plurality of client devices, the simulation information associated with the authoritative simulation state, wherein one or more simulation instances of the first client device of the plurality of client devices are updated with the simulation information.

Clause 12: The system of clause 11, wherein the at least one processor is further configured to: communicate via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

Clause 13: The system of clauses 11 or 12, wherein the at least one processor is further configured to: update a current simulation state of the first simulation instance of the one or more simulation instances based on the simulation information routed by the central authority to each client device of the plurality of client devices; or update the current simulation state based on the at least one input transmitted by at least one of the client devices to another client device of the plurality of client devices.

Clause 14: The system of clauses 11-13, wherein the at least one processor is further configured to: communicate the simulation information by a central authority to at least one client device of the plurality of client devices based on the at least one input received by the central authority from at least one other client device of the plurality of client devices.

Clause 15: The system of clauses 11-14, wherein the at least one processor is further configured to: execute a master simulation instance, the master simulation instance comprising a master simulation state, wherein the master simulation state provides a source of the authoritative simulation state, the authoritative simulation state comprising at least a subset of the master simulation state.

Clause 16: The system of clauses 11-15, wherein the at least one processor is further configured to: provide a reconciliation window, the reconciliation window including a duration of a network latency time that establishes a maximum latency time between the central authority and at least one client device of the plurality of client devices; and periodically update the master simulation state of the master simulation instance based on the duration of the reconciliation window elapsing.

Clause 17: The system of clauses 11-16, wherein the at least one processor is further configured to: detect one or more network characteristics related to a network latency in at least one communication between the first client device and a second client device; determine from the one or more network characteristics that the at least one communication arrived on time or that a first variation between the first client device and the second client device satisfies a first threshold value of variation in the network latency; and in response to determining that the first variation of a network latency satisfies the first threshold value of variation in network latency, initiate a protective measure by terminating a connection between the first client device and the second client device.

Clause 18: The system of clauses 11-17, wherein the at least one processor is further configured to: determine contents of a communication between the first client device and a second client device; determine a second variation in the contents of the communication between the first client device and the second client device, satisfies a first threshold value of variation in a network latency; and in response to determining that a first variation in packet contents satisfies the first threshold value of variation in the network latency, initiate a protective measure by terminating a connection between the first client device and the second client device.

Clause 19: The system of clauses 11-18, wherein a central authority is configured to transmit a decryption key to the second client device, and the at least one processor is further configured to: transmit an encrypted packet to the second client device of the plurality of client devices; transmit a corresponding decryption key to the second client device, wherein the decryption key is sent by a client device of the plurality of client devices or the central authority; and generate a first transmission time indicating when to transmit the decryption key from the central authority to the second client device of the plurality of client devices, the first transmission time based on subtracting a first duration from a second transmission time, wherein the first duration is based on a difference between a second duration from a third duration, wherein the first transmission time is determined by: v=t−(p−l) such that v is equal to the first transmission time, t is equal to the second transmission time, l is equal to the second duration, and p is equal to the third duration, wherein the second duration is based on a latency or distance between the first client device and the second client device, the third duration is based on the delayed processing penalty associated with the second client device.

Clause 20: A non-transitory computer-readable medium having instructions stored thereon that, when executed by at least one computing device, cause the at least one computing device to: obtain at least one input associated with an authoritative simulation state from a first client device of a plurality of client devices, the first client device executing a first simulation instance; associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and route simulation information to the plurality of client devices, the simulation information associated with the authoritative simulation state, wherein one or more simulation instances of the first client device of the plurality of client devices are updated with the simulation information.

These and other features and characteristics of the present disclosure, as well as the methods of operation and functions of the related elements of structures and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the disclosed subject matter.

### BRIEF DESCRIPTION OF THE DRAWINGS

Additional advantages and details are explained in greater detail below with reference to the non-limiting, exemplary embodiments that are illustrated in the accompanying schematic figures, in which:

FIG. 1 is a schematic diagram of a system for reducing artifacts in networked simulations with a combined peer-to-peer and authoritative network architecture according to some non-limiting embodiments or aspects;

FIG. 2 is a schematic diagram of a system for reducing artifacts in networked simulations with a routing server according to some non-limiting embodiments or aspects;

FIG. 3 is a flow diagram of a method for reducing artifacts in networked simulations according to some non-limiting embodiments or aspects;

FIG. 4 is a flow diagram of a method for reducing artifacts in networked simulations according to some non-limiting embodiments or aspects; and

FIG. 5 is a schematic diagram of example components of one or more devices of FIG. 1 and/or FIG. 2 according to some non-limiting embodiments or aspects.

### DETAILED DESCRIPTION

For purposes of the description hereinafter, the terms “end,” “upper,” “lower,” “right,” “left,” “vertical,” “horizontal,” “top,” “bottom,” “lateral,” “longitudinal,” and derivatives thereof shall relate to the embodiments as they are oriented in the drawing figures. However, it is to be understood that the embodiments may assume various alternative variations and step sequences, except where expressly specified to the contrary. It is also to be understood that the specific devices and processes illustrated in the attached drawings, and described in the following specification, are simply exemplary embodiments or aspects of the disclosed subject matter. Hence, specific dimensions and other physical characteristics related to the embodiments or aspects disclosed herein are not to be considered as limiting.

No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Furthermore, as used herein, the term “set” is intended to include one or more items (e.g., related items, unrelated items, a combination of related and unrelated items, and/or the like) and may be used interchangeably with “one or more” or “at least one.” Where only one item is intended, the term “one” or similar language is used. Also, as used herein, the terms “has,” “have,” “having,” or the like are intended to be open-ended terms. Further, the phrase “based on” is intended to mean “based at least partially on” unless explicitly stated otherwise.

As used herein, satisfying a threshold may refer to a value (e.g., a variation in transmission time, a variation in network latency, variation in processing time of inputs, variation in simulation states, variation in client to client communications etc.) being greater than the threshold, more than the threshold, higher than the threshold, greater than or equal to the threshold, less than the threshold, fewer than the threshold, lower than the threshold, less than or equal to the threshold, equal to the threshold, etc.

As used herein, the term “communication” or “communications” may refer to the reception, receipt, transmission, transfer, provision, and/or the like of data (e.g., information, signals, messages, instructions, commands, and/or the like). For one unit (e.g., a device, a system, a component of a device or system, combinations thereof, and/or the like) to be in communication with another unit means that the one unit is able to directly or indirectly receive information from and/or transmit information to the other unit. This may refer to a direct or indirect connection (e.g., a direct communication connection, an indirect communication connection, and/or the like) that is wired and/or wireless in nature. Additionally, two units (e.g., devices, etc.) may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit processes information received from the first unit and communicates the processed information to the second unit. In some non-limiting embodiments or aspects, a communication (e.g., a message, a packet, etc.) may be used to encapsulate and transfer data. The communication may encompass various forms, including network packets (such as data packets or similar units), network frames, data packets, communication units, information exchange, transmission, networked data, message unit, and/or the like. The communication process involves the transfer of these messages, which may contain input, updates, or other relevant information, between different client devices, and/or the central authority, within the networked simulation system. It will be appreciated that numerous other arrangements are possible.

As used herein, the term “computing device” may refer to one or more electronic devices configured to process data. A computing device may, in some examples, include the necessary components to receive, process, and output data, such as a processor, a display, a memory, an input device, a network interface, and/or the like. A computing device may be a mobile device. As an example, a mobile device may include a cellular phone (e.g., a smartphone or standard cellular phone), a portable computer, a wearable device (e.g., watches, glasses, lenses, clothing, and/or the like), a personal digital assistant (PDA), and/or other like devices. A computing device may also be a desktop computer or other form of non-mobile computer.

As used herein, the terms “client”, “client device” and “computing device” may refer to one or more client-side devices or systems (e.g., remote from a central authority) used to initiate or facilitate a network connection (e.g., a connection to a networked simulation). As an example, a client device may refer to one or more electronic devices operated by a user, one or more personal computers used by a user, one or more mobile devices used by a user, and/or the like. In some non-limiting embodiments or aspects, a client device may be an electronic device configured to communicate with one or more networks and execute or facilitate networked simulations. For example, a client device may include one or more computers, portable computers, laptop computers, tablet computers, mobile devices, cellular phones, wearable devices (e.g., watches, glasses, lenses, clothing, and/or the like), PDAs, and/or the like. Moreover, a “client” may also refer to an entity (e.g., a user, a corporation, and/or the like) that owns, utilizes, and/or operates a client device for executing simulations (e.g., for executing networked simulations within a networked connected to a central authority).

As used herein, the term “server” may refer to or include one or more computing devices that are operated by or facilitate communication and processing for multiple parties (e.g., clients, clients devices, users, and/or the like) in a network environment, such as the Internet, although it will be appreciated that communication may be facilitated over one or more public or private network environments and that various other arrangements are possible. Further, multiple computing devices (e.g., servers, mobile devices, etc.) directly or indirectly communicating in the network environment may constitute a “system.” Reference to “a server” or “a processor,” as used herein, may refer to a previously-recited server and/or processor that is recited as performing a previous step or function, a different server and/or processor, and/or a combination of servers and/or processors. For example, as used in the specification and the claims, a first server and/or a first processor that is recited as performing a first step or function may refer to the same or different server and/or a processor recited as performing a second step or function.

As used herein, the term “central authority” may refer to or include one or more computing entities or systems that operates in a central and coordinating role in a networked simulation. The central authority manages the communication and interaction among multiple client devices participating in the simulation. The central authority may be responsible for processing inputs received from client devices, updating the simulation state, and distributing relevant information to maintain synchronization among the distributed simulations. The central authority acts as a central hub or mediator, facilitating communication and ensuring consistency in the simulation by processing and coordinating inputs from various client devices. The central authority maintains order, resolves conflicts, and synchronizes simulated scenarios across the network.

As used herein, the term a “processing delay penalty”, “penalty”, or “PDP” may refer to one or more techniques provided in a networked simulation system to enforce a minimum acceptable duration that must elapse between the generation of an initial input in a client device and the subsequent time associated with an authoritative simulation state influenced by or based on that input. This penalty is designed to prevent one or more clients, one or more client devices, and/or the like, from expecting immediate updates to one or more local simulation states following the initiation of an input. In some examples, the PDP aims to introduce a temporal delay, ensuring that the one or more clients (or client devices) provides a specified time for the authoritative simulation state to be updated or influenced by their inputs before expecting changes in their local simulations. By enforcing this delay, the system promotes synchronization and consistency across each of the client devices, incentivizes each client to communicate on time with the central authority and/or the other client devices, to avoid increasing delayed processing penalties, and thereby prevents or minimizes premature updates that could lead to discrepancies or artifacts in the networked simulation. In some non-limiting embodiments or aspects, the PDP involves associating a specific time duration with each client device, reflecting the minimum acceptable time that should elapse before the authoritative state reflects the impact of the client's input. In this way, the PDP contributes to the overall integrity and coherence (e.g., a consistency or agreement of simulation states among different client devices of the networked simulation, etc.) by regulating the timing of updates across the distributed simulation instances. In some non-limiting embodiments or aspects, to discourage a delayed communication from a client, encryption may be used with the processing delay penalty to eliminate the possibility for a malicious client to gain an advantage relative to another client (e.g., over another client, etc.). For example, by encrypting a packet for a first client device, the central authority or another client device may control access to the packet until a decryption key is sent and received by the first client device. In such an example, the first client device must wait until receiving the decryption key for the specific encrypted communication (e.g., the encrypted packet, etc.) and may be unable to access the encrypted package until receiving the decryption key. In this way, the central authority or another client device may control access to a packet.

As used herein, the term an “authoritative simulation state” or “authoritative state” may refer to the validated or confirmed state of the simulation that is recognized as accurate and accepted by the central authority. The authoritative simulation state serves as the reference point for the current state of the networked simulation (e.g., a virtual environment or situation that is being simulated by a networked system to represent various scenarios, such as virtual worlds, interactive game environments, or complex systems emulated for testing purposes, and encompasses the collective state of the virtual elements, interactions, and dynamics that are being modeled within the networked simulation). For example, in a multiplayer online game, the networked simulation might include the positions or movements of multiple players, the state of the artificial game world, various in-game events, and/or the like. The networked simulation may represent the behavior of the system under different conditions. The authoritative simulation state ensures that all participating devices maintain a consistent and accurate representation of this networked simulation. In such a scenario, each client device may be programmed or configured to align its local simulation instance with the authoritative simulation state. The authoritative simulation state maintains reliability and trust. The authoritative simulation state ensures that all participating client devices have a consistent and agreed-upon view of the networked simulation, promoting coherence (e.g., a consistency or agreement of simulation states among different client devices, etc.) across the networked simulation. In some examples, clients may derive or determine the authoritative state based upon verified inputs from the central authority. For example, if the clients are deterministic then a master simulation does not need to exist on the central authority. In such an example, clients are capable of determining the authoritative state based on the client inputs communicated from the central authority for generating any given frame.

As used herein, the term, “client-side prediction” refers to a technique used in networked simulations where a client device autonomously predicts the outcomes of user inputs locally without waiting for confirmation from a central server. The purpose of client-side prediction is to enhance the user experience by providing quicker responses to user actions, making the simulation feel more responsive. This approach allows clients to anticipate and display the potential effects of user inputs instantaneously, for example, to provide or contribute to a seamless and interactive simulation environment. Reconciliation may be employed to align these local predictions with the authoritative simulation state during the reconciliation process, ensuring consistency across all connected client devices.

As used herein, the term a “master simulation instance” or “master simulation” may refer to a comprehensive simulation framework that serves as a source (e.g., a base, a foundation, etc.) for generating the authoritative simulation state. The master simulation instance comprises a master simulation state, which is a representation of the simulated environment at a particular point in time. The master simulation state within the master simulation instance includes essential information about the state of the networked simulation, encompassing various elements, variables, conditions, and/or the like. In some examples, a master simulation instance may serve as the primary reference or source for determining the authoritative simulation state, which is a subset or specific configuration derived from the master simulation state. The master simulation instance comprises a comprehensive view (e.g., a holistic, complete view, or information for generating such a view, etc.) of the networked simulation, and the master simulation state within the networked simulation forms the basis for defining the authoritative simulation state. The authoritative simulation state represents a selected portion (e.g., snapshot, geographic location, spatial area, etc.) of the master simulation state, reflecting the current state of the networked simulation for that selected portion as determined by the networked system.

As used herein, the term a “simulation information” may refer to the data or updates transmitted between client devices or transmitted between client devices and a central authority in a networked simulation system. This information includes details about the state of the simulation, inputs from individual clients, necessary updates to synchronize and maintain consistency among the different simulation instances running on various client devices, and/or the like. The simulation information facilitates the coordination and interaction between clients, allowing them to maintain a coherent and shared understanding of the simulated scenario or system.

As used herein, the term a “simulation instance” may refer to an individual execution or representation of a simulated scenario or system on a client device within a networked simulation. Each client device may run its own simulation instance (e.g., an individual execution or instance of the simulation process that is running independently on a specific client device, etc.), processing inputs, updating its local simulation state, and interacting with other simulation instances on different client devices. These simulation instances collectively contribute to the overall networked simulation, such that information is exchanged among a plurality of clients to achieve a synchronized and consistent representation of the networked simulation across each of the connected devices.

As used herein, the term a “minimum acceptable duration” refers to the shortest allowable time period that must elapse between the occurrence of an initial instance (e.g., generation of an input on a client device) and a subsequent instance associated with an authoritative simulation state influenced by or based on that initial instance. The minimum acceptable duration serves as a constraint that ensures clients will wait for a specified amount of time before expecting the authoritative simulation state to be updated or influenced by their inputs. This constraint helps maintain the integrity and consistency of the networked simulation by allowing sufficient time for communication, processing, and synchronization among the connected client devices.

As used herein, the term a “reconciliation window” or “reconciliation period” refers to a specific duration of time allocated by the central authority for receiving inputs provided by the client devices that the central authority may use to generate an updated master simulation state. This reconciliation window reduces the amount of computation by the central authority to generate the master simulation state. The duration of the reconciliation window may be influenced by factors such as network latency, the need to accommodate communication delays between the central authority and client devices, and/or the like.

As used herein, the term “input” refers to instructions, data, commands, and/or the like, generated by a user or a client device participating in the networked simulation. Input may influence the evolution of the simulation states in the networked environment. This input could represent actions taken by a user within a simulated environment, such as a command to perform a specific action like jumping, running, shooting, and/or the like, in a virtual space. For example, if a user initiates a jump command and then sends it to the central authority, the command or data associated with the jump action is considered an input. In the broader context of the networked simulation system, the input is a piece of information that affects the simulation state when processed. This input is then transmitted to the central authority, which may use it to update the authoritative simulation state and subsequently inform other client devices about the changes in the simulated scenario or system.

As used herein, the term “routing device”, “intermediary device”, or “routing server” refers to a component within the networked simulation system that facilitates communication between different entities (e.g., one or more client devices, the central authority, etc.). The routing device is responsible for transmitting intermediary communications, serving as an intermediary or go-between for messages exchanged between various participants in the simulation. The routing device may relay messages from one client device to another, from a client device to the central authority, or from the central authority to a client device. The communication between these entities may not occur via a direct connection and may be replaced by communication with the routing device. In such an example, the routing device acts as an intermediary, receiving messages, forwarding messages, ensuring that the communication flows efficiently through the networked simulation architecture, and/or the like. The routing device may provide a key function of managing the routing and transmission of messages within the networked simulation system, facilitating indirect communication between different entities (e.g., devices, etc.) involved in the simulation.

As used herein, the term “transmission characteristics” or “characteristics related to the transmission” refers to various attributes or features associated with the process of transmitting information within the networked simulation system. These characteristics may comprise different aspects that contribute to the effectiveness and reliability of the transmission. For example, the aspects may include expected time (e.g., an anticipated or planned duration within which a transmission is expected to occur, a pre-determined timeframe based on the system design or specifications, etc.), realized time (e.g., the actual time taken for a transmission to occur, either an observed or measured duration starting from the initiation of the transmission to its completion in practice, etc.), transmission reliability (e.g., a degree to which the transmission process can be trusted to deliver information accurately and consistently, maintaining the integrity of the simulation, etc.), transmission efficiency (e.g., an effectiveness of the transmission process in terms of utilizing network resources optimally and ensuring timely delivery of information, etc.), latency management (e.g., handling of latency to control the delay between the initiation of a transmission and the actual reception of the transmitted information, for real-time or near-real-time simulations, etc.), synchronization (e.g., aligning different components of the simulation system in time to ensure information is transmitted and received in an orderly manner, etc.), error handling (e.g., detecting and addressing errors or discrepancies that may occur during a transmission between the central authority, client devices, or the intermediary server, to ensure the accuracy of the transmitted information, etc.). In some examples, expected time versus realized time relates to the planned duration for a transmission (expected time) versus the actual duration observed during the transmission (realized time). In some cases, latency between two clients (e.g., a first client and a second client, etc.) or a first client and a central authority is based on characteristics related to a transmission or determined by measuring transmission times (e.g., a transmission duration, etc.) between a first client and a second client or between a first client and a central authority.

As used herein, the term “audit” or “packet auditing” may refer to a process of determining or capturing variations in expected characteristics of a transmission. These characteristics can include content, expected content, time of receipt, or other relevant attributes defined in the system. In some examples, audit involves a comparison between the expected characteristics (those anticipated or predefined by the system) and the realized characteristics (what actually occurred or was observed). The audit may verify whether the realized characteristics align with the expected ones. The comparison is done to check whether the observed characteristics satisfy acceptable thresholds. These thresholds serve as criteria to assess the validity and conformity of the transmission. If the observed characteristics fall within acceptable thresholds, it indicates that the transmission is considered acceptable. The audit detects discrepancies or inconsistencies in the characteristics of transmissions by comparing and ensuring that transmitted packets meet the expected criteria to ensure they align with expected characteristics, and any deviations from the predefined criteria may trigger further actions or decisions within the networked simulation system.

As used herein, the term “on time” refers to executing or completing a specific operation (e.g., transmitting, storing, or processing information, inputs etc.), within an expected or desired timeframe. This timeframe may be predefined based on system specifications or requirements, and implies that the system can meet or adhere to the planned schedule for various activities, ensuring that processes occur within acceptable time limits and associated with the concept of timely and efficient execution of tasks, minimizing delays, maintaining synchronization within a simulation framework, and/or the like. For example, in the context of networked simulations, where real-time or near-real-time interactions are crucial, being “on time” would mean that transmissions, updates, or responses occur promptly and within the expected timeframes, contributing to a smooth and responsive simulation experience.

As used herein, the term a “protective measure” refers to an action or device implemented to safeguard the system's integrity, security, or functionality under certain conditions. For example, protective measures are designed to prevent or mitigate potential risks, disruptions, or undesirable events that could compromise the reliability or fairness of the networked simulation. The protective measure mentioned may involve terminating a connection between client devices (e.g., stopping or blocking the flow of data packets between peers in a direct connection, intentionally preventing the exchange of information between specific client devices, etc.), such as, for example, in response to detected variations in network latency satisfying (e.g., surpassing, coming in below, etc.) a specified threshold. This termination of the connection acts as a protective measure to prevent potential issues caused by abnormal network conditions (e.g., due to perceived malicious clients via things like delayed transmission, etc.), ensuring that the continued stability and proper functioning of the networked simulation will remain. In some cases, a protective measure is a proactive or responsive step taken within the system to maintain its robustness, resilience, adherence to specified performance criteria, and/or the like, particularly for anomalies that arise during the simulation process.

As used herein, the term “a frame” may refer to a time interval (e.g., frame rate, time step, tick, and/or the like) of a simulation (e.g., a simulation that is being executed) in which the internal steps (e.g., internal instructions, internal code, and/or the like) of the simulation are executed to provide an output from an input (e.g., a single input, a plurality of inputs, and/or the like).

As used herein, the term a “packet” refers to a unit of data transmitted over a network. It is a standardized format for data that includes both the actual information being transmitted and control information necessary for routing and delivery. Packets are used to efficiently send and receive data between devices connected to a network. A packet may include the following: data payload (e.g., actual information or content being transmitted, such as user input, simulation data, other relevant data, etc.), a header (e.g., contains control information required for the packet to be properly routed and delivered, information may include source and destination addresses, error-checking data, sequencing information, etc.), a footer or trailer (e.g., additional control information to ensure the integrity of the packet during transmission, etc.), source and destination addresses (e.g., indicates the origin and intended recipient of the packet, etc.), sequence number (e.g., packets may be numbered to help in the proper ordering of data, especially if the data is split into multiple packets for transmission, etc.).

As used herein, the term “encryption” refers to a process of converting information or data into a coded or encrypted form (cipher) or making information less readable, to secure it from unauthorized access or interception. Encryption often involves the use of an encryption key, and the encrypted data can only be deciphered or decrypted using the corresponding decryption key. The encryption may involve using a piece of information that is kept secret (e.g., a key) to perform cryptographic operations. Encryption may also include techniques for encoding data or obfuscating information to make data less understandable, simple substitution, and/or the like, without employing strong cryptographic algorithms and keys.

As used herein, the term “decryption” refers to the reverse process of encryption. It involves converting coded or encrypted data back into its original, readable form using a decryption key. The decryption key is necessary to unlock the encrypted information.

As used herein, the term a “transmission time” refers to the duration taken for data (e.g., simulation information, updates, communication messages, etc.) to be sent from one point in the network to another (e.g., the time it takes for a packet or message to travel from the sender to the receiver over the network infrastructure, etc.). The transmission time is influenced by various factors, including: network latency (e.g., a delay introduced by the network infrastructure, which includes factors like propagation delay, transmission delay, and processing delay, etc.), network congestion (e.g., if the network experiences congestion, it can lead to increased transmission time as packets may need to wait in queues, etc.), routing delays (e.g., the time taken to determine the optimal route for transmitting data from the source to the destination, etc.), packet processing time (e.g., the time taken by devices (e.g., routers or switches) to process and forward the packets, etc.).

Non-limiting embodiments or aspects of the disclosed subject matter are directed to improved systems, methods, and computer program products for reducing artifacts in networked simulations. For example, non-limiting embodiments or aspects of the disclosed subject matter provide improved execution of a master simulation instance. The master simulation instance may include a master simulation state (e.g., a state of the master simulation instance based on a frame of a plurality of frames of the master simulation instance). The master simulation state may correspond to at least one frame of a plurality of frames of the master simulation instance. An input (e.g., input data associated with inputs from a user to a client device where the user is associated with the client device, input data associated with inputs to an input device of a client device, and/or the like) may be received by a central authority from a first client device of a plurality of client devices connected to the central authority. The first client device may execute a first simulation instance associated with the master simulation instance (e.g., the master simulation instance and the first simulation instance may include separate instances of a networked simulation). The central authority may route the input received from the first client device to each client device of a plurality of client devices based on receiving the input from the first client device. Each client device of the plurality of client devices may execute a simulation instance of a plurality of simulation instances. Each simulation instance of the plurality of simulation instances may include a simulation state. Each simulation instance of the plurality of simulation instances may be associated with the master simulation instance (e.g., the master simulation instance and each simulation instance of the plurality of simulation instances may include separate instances of a networked simulation). The central authority may update the master simulation state of the master simulation instance based upon the duration of a reconciliation window elapsing, to produce an updated master simulation state based on the input from the first client device of the plurality of client devices. The duration of the reconciliation window may include a modifiable predetermined duration that establishes (e.g., represents, includes, and/or the like) a maximum latency time between the central authority and each client device of the plurality of client devices.

Non-limiting embodiments or aspects of the disclosed subject matter may also provide updates to the simulation state of each simulation instance of the plurality of simulation instances based on the central authority transmitting simulation information to each client device of the plurality of client devices.

Non-limiting embodiments or aspects of the disclosed subject matter may also transmit a request from a central authority to each client device of a plurality of client devices. The request may include a response from each client device of the plurality of client devices. The central authority may receive a response from a client device (e.g., one or more client devices) of the plurality of client devices based on the request. The central authority may measure a duration for the client device to respond to the request. The duration may be measured from a first time when the request was transmitted from the central authority to a second time when the response was received by the central authority from the client device of the plurality of client devices. The central authority may determine a penalty to associate with each client device of the plurality of client devices based on the duration for the client device to respond to the request. In some cases, the penalty associated with the client device may be less than the duration (e.g., only a half of the duration, etc.).

Such improved embodiments or aspects may leverage a reconciliation window in which the central authority may delay generating an updated master simulation state for a duration of time equal to the maximum allowed latency between a client device and the central authority. When the central authority receives inputs from one or more client devices, the central authority may route the inputs to each other client device connected to the central authority instantly. Some embodiments or aspects provide techniques and systems that provide a network architecture using a central authority executing a networked simulation along with a combined peer-to-peer implementation. In this way, prior to receiving the updated master simulation state, a client device may process the inputs received by one or more client devices to generate an updated simulation state (e.g., approximated master simulation state, updates, etc.) for the simulation instance executing on the client device, allowing the client device to generate an approximated update, reducing the occurrence of network artifacts and reducing any advantages for a first user using a first client device against a second user using a second client device (e.g., peeker's advantage, and/or the like) that may arise.

Furthermore, such improved embodiments or aspects allow the central authority to wait until each input (e.g., the inputs triggered and/or originated by one or more client devices, etc.) is transmitted from a client device to the central authority within the reconciliation window, such that the central authority may process the inputs (e.g., the inputs from one or more client devices) in concert. After the central authority has processed the inputs transmitted within the reconciliation window, the central authority then may update the master simulation state of the master simulation instance executing on the central authority and the central authority may send the results (e.g., the central authority may send updates to a simulation state of one or more simulation instances executing on one or more client devices, etc.) to the plurality of client devices.

The one or more client devices may correct (e.g., update, add to, replace, etc.) the simulation state of the simulations executing on the one or more client devices based on an updated master simulation state when the updated master simulation state is received from the central authority after the reconciliation window has elapsed. In this way, the central authority may permit more client devices to participate simultaneously without drastically increasing the resources used and while reducing the occurrence of network artifacts that may negatively impact an experience of a user using (e.g., operating) a client device.

Such improved embodiments or aspects may eliminate the possibility for a malicious client to gain an advantage by sending conflicting and/or delayed inputs to each individual client device connected to the networked simulation. In some non-limiting embodiments or aspects, the central authority and/or the one or more client devices (e.g., including connected client devices, etc.) may detect a malicious client transmitting delayed inputs to the central authority or any other client device and terminate a connection with the malicious client.

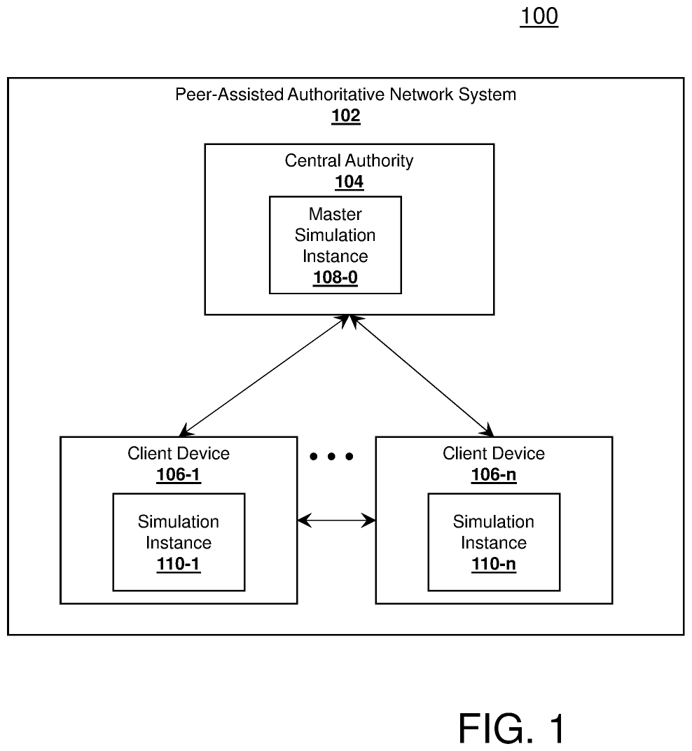

FIG. 1 illustrates a system 100 for reducing artifacts in networked simulations using a combined peer-to-peer and authoritative network architecture according to some non-limiting embodiments or aspects. System 100 may include peer-assisted authoritative network system 102, central authority 104, client device 106-1 to client device 106-n (e.g., a plurality of client devices, referred to individually as client device 106 and collectively as client devices 106 where appropriate), master simulation instance 108-0 (e.g., a simulation instance executing on central authority 104, etc.), referred to as simulation instance 108 or master simulation instance 108. Simulation instance 110-1 through 110-n (e.g., a plurality of simulation instances, referred to individually as simulation instance 110 and collectively as simulation instances 110 where appropriate, for example, simulation instances executing on client devices 106).

Peer-assisted authoritative network system 102 may include a computing device, such as a server (e.g., a single server, such as central authority 104), a group of servers, and/or other like devices. In some non-limiting embodiments or aspects, peer-assisted authoritative network system 102 may include a processor and/or memory as described herein. In some non-limiting embodiments or aspects, peer-assisted authoritative network system 102 may include a plurality of client devices 106 (e.g., client devices 106-1 to 106-n). In some non-limiting embodiments or aspects, peer-assisted authoritative network system 102 may include one or more servers and/or one or more client devices executing instructions (e.g., software instructions) that cause peer-assisted authoritative network system 102 to perform one or more steps of methods as described herein.

Central authority 104 may include a computing device, such as a server and/or at least one processor (e.g., a multi-core processor), for example a central processing unit (CPU), an accelerated processing unit (APU), a graphics processing unit (GPU), a microprocessor, and/or the like. In some non-limiting embodiments or aspects, central authority 104 may be programmed to perform one or more steps of methods described herein. In some non-limiting embodiments or aspects, central authority 104 may be in communication with one or more client devices 106 (e.g., client devices 106-1 to 106-n). In some non-limiting embodiments or aspects, central authority 104 may be capable of receiving information from and/or communicating (e.g., transmitting) information to one or more client devices 106. In some non-limiting embodiments or aspects, central authority 104 may execute an instance of a simulation (e.g., an instance of a networked simulation, a simulation executing on a server, master simulation instance 108-0, and/or the like).

Client devices 106-1 to 106-n may include one or more computing devices operable by one or more users. In some non-limiting embodiments or aspects, client devices 106-1 to 106-n may communicate with central authority 104 via a communication network. For example, client devices 106-1 to 106-n may transmit information to and/or receive information from central authority 104. In some non-limiting embodiments or aspects, client devices 106-1 to 106-n may communicate with other client devices 106. For example, client devices 106-1 to 106-n may transmit information to and/or receive information from other client devices 106-1 to 106-n. In some non-limiting embodiments or aspects, client devices 106-1 to 106-n may be capable of executing an instance of a simulation (e.g., an instance of a networked simulation). For example, client devices 106-1 to 106-n may execute simulation instances 110-1 to 110-n respectively (e.g., client device 106-1 may execute simulation instance 110-1, client device 106-2 may execute simulation instance 110-2, etc.).

Master simulation instance 108-0 may include an instance of a simulation executing on a computing device (e.g., a server, central authority 104, and/or the like). In some non-limiting embodiments or aspects, master simulation instance 108-0 may include one or more instructions (e.g., software instructions, etc.) executing on a computing device. For example, central authority 104 may execute master simulation instance 108-0. In some non-limiting embodiments or aspects, master simulation instance 108-0 may include a record (e.g., history, timeline, state, and/or the like) of a simulation executing on a computing device. For example, master simulation instance 108-0 may include a simulation record of master simulation instance 108-0 where the simulation record may be stored by central authority 104 (e.g., in memory of central authority 104, in a database in communication with central authority 104, and/or the like). In some non-limiting embodiments or aspects, master simulation instance 108-0 may include an instance of a networked simulation executing on a central computing device (e.g., a server, central authority 104, and/or the like) such that master simulation instance 108-0 executes as a master simulation (e.g., a master simulation record, an instance of a simulation in which other simulation instances synchronize with, an instance of a simulation that is capable of broadcasting updates out to other instances of the simulation, and/or the like).

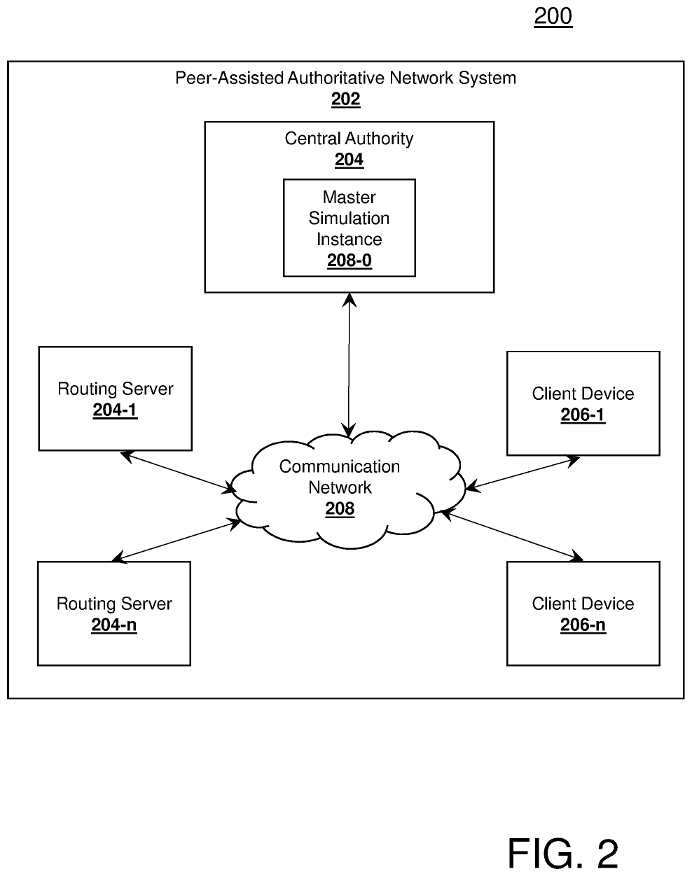

In some non-limiting embodiments or aspects, master simulation instance 108-0 may transmit (e.g., broadcast, etc.) changes to a state of master simulation instance 108-0 (e.g., updates, etc.), to simulation instances 110-1 to 110-n via central authority 104, client devices 106, and/or a communication network (e.g., shown in FIG. 2). For example, after central authority 104 applies inputs to master simulation instance 108-0, master simulation instance 108-0 may process the inputs and master simulation instance 108-0 may update the state of master simulation instance 108-0 based on the inputs. Master simulation instance 108-0 may transmit the updates to the state of master simulation instance 108-0 to simulation instances 110 executing on client devices 106 such that simulation instance 110 may update the state of each simulation instances 110-1 to 110-n based on the state of master simulation instance 108-0 (e.g., simulation instances 110 may synchronize states of client devices 106 to match the state of master simulation instance 108-0).

Simulation instances 110-1 to 110-n may include one or more instances of a simulation executing on one or more computing devices 106 (e.g., one or more client devices 106, client devices 106-1 to 106-n, etc.). In some non-limiting embodiments or aspects, simulation instances 110-1 to 110-n may include one or more instructions (e.g., software instructions, etc.) executing on one or more computing devices. For example, client devices 106-1 to 106-n may execute simulation instances 110-1 to 110-n respectively (e.g., client device 106-1 may execute simulation instance 110-1, client device 106-2 may execute simulation instance 110-2, etc.). In some non-limiting embodiments or aspects, simulation instances 110-1 to 110-n may include one or more instances of a networked simulation executing on a computing device connected to (e.g., in communication with, etc.) a central computing device (e.g., a server, central authority 104, etc.). For example, simulation instances 110-1 to 110-n may include one or more instances of a networked simulation executing on client devices 106-1 to 106-n where client devices 106-1 to 106-n are connected to central authority 104.

The number and arrangement of systems and devices shown in FIG. 1 are provided as an example. There may be additional systems and/or devices, fewer systems and/or devices, different systems and/or devices, and/or differently arranged systems and/or devices than those shown in FIG. 1. Furthermore, two or more systems or devices shown in FIG. 1 may be implemented within a single system or device, or a single system or device shown in FIG. 1 may be implemented as multiple, distributed systems or devices. Additionally or alternatively, a set of systems (e.g., one or more systems) or a set of devices (e.g., one or more devices) of system 100 may perform one or more functions described as being performed by another set of systems or another set of devices of system 100.

FIG. 2 illustrates a diagram of a non-limiting embodiment or aspect of system 200 in which exemplary systems, products, and/or methods, as described herein, may be implemented. As shown in FIG. 2, system 200 may include peer-assisted authoritative network system 202, routing server 204-1 to routing server 204-n (e.g., a plurality of routing servers, referred to individually as routing server 204 and collectively as routing servers 204 where appropriate), client device 206-1 to client device 206-n (e.g., a plurality of client devices, referred to individually as client device 206 and collectively as client devices 206 where appropriate), and communication network 208. In some non-limiting embodiments or aspects, each of routing servers 204, client devices 206, and/or communication network 208 may be implemented by (e.g., as part of) peer-assisted authoritative network system 202. In some non-limiting embodiments or aspects, at least one of each of routing servers 204, client devices 206, and/or communication network 208 may be implemented by (e.g., part of) another system, another device, another group of systems, or another group of devices, separate from or including peer-assisted authoritative network system 202, such as routing server 204, client device 206, and/or the like.

Peer-assisted authoritative network system 202 may include one or more devices capable of receiving information from and/or communicating information to routing servers 204 and/or client devices 206 via communication network 208. For example, peer-assisted authoritative network system 202 may include a computing device, such as a central authority (e.g., a central server, and/or the like), a client device, a group of servers, a routing device, and/or other like devices. In some non-limiting embodiments or aspects, peer-assisted authoritative network system 202 may be associated with a server as described herein. In some non-limiting embodiments or aspects, peer-assisted authoritative network system 202 may be in communication with a data storage device, which may be local or remote to peer-assisted authoritative network system 202. In some non-limiting embodiments or aspects, peer-assisted authoritative network system 202 may be capable of receiving information from, storing information in, communicating information to, or searching information stored in the data storage device.

Routing server 204 may include one or more devices capable of receiving information from and/or communicating information to peer-assisted authoritative network system 202, a central authority, and/or client devices 206 via communication network 208. For example, routing server 204 may include a computing device, such as a server, a group of servers, and/or other like devices. In some non-limiting embodiments or aspects, routing server 204 may be associated with a server as described herein.

Client device 206 may include one or more devices capable of receiving information from and/or communicating information to peer-assisted authoritative network system 202 and/or routing server 204 via communication network 208. Additionally or alternatively, each client device 206 may include a device capable of receiving information from and/or communicating information to other client devices 206, and/or a central authority via communication network 208, another network (e.g., an ad hoc network, a local network, a private network, a virtual private network, and/or the like), and/or any other suitable communication technique. For example, client device 206 may include a user device and/or the like.

Communication network 208 may include one or more wired and/or wireless networks. For example, communication network 208 may include a cellular network (e.g., a long-term evolution (LTER) network, a third generation (3G) network, a fourth generation (4G) network, a fifth generation (5G) network, a code division multiple access (CDMA) network, and/or the like), a public land mobile network (PLMN), a local area network (LAN), a wide area network (WAN), a metropolitan area network (MAN), a telephone network (e.g., the public switched telephone network (PSTN)), a private network (e.g., a private network associated with peer-assisted authoritative network system 202), an ad hoc network, an intranet, the Internet, a fiber optic-based network, a cloud computing network, and/or the like, and/or a combination of these or other types of networks.

The number and arrangement of systems, devices, and/or networks shown in FIG. 2 are provided as an example. There may be additional systems, devices, and/or networks; fewer systems, devices, and/or networks; different systems, devices, and/or networks; and/or differently arranged systems, devices, and/or networks than those shown in FIG. 2. Furthermore, two or more systems or devices shown in FIG. 2 may be implemented within a single system or device, or a single system or device shown in FIG. 2 may be implemented as multiple, distributed systems or devices. Additionally or alternatively, a set of systems (e.g., one or more systems) or a set of devices (e.g., one or more devices) of system 200 may perform one or more functions described as being performed by another set of systems or another set of devices of system 200.

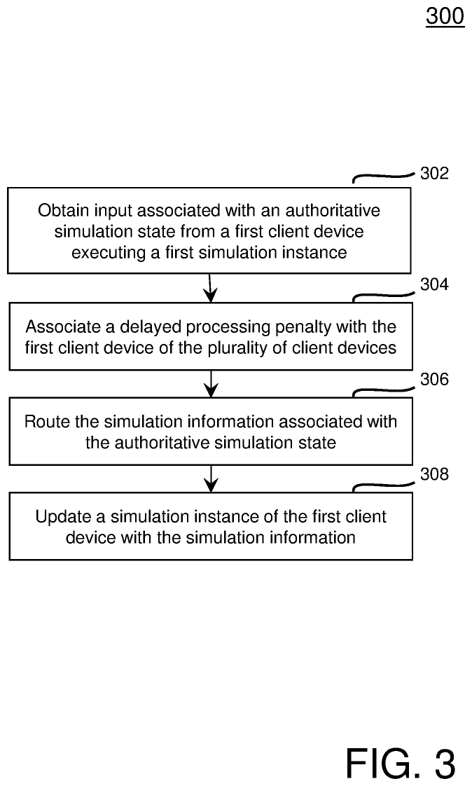

Referring now to FIG. 3, shown is process 300 for reducing artifacts in networked simulations according to some non-limiting embodiments or aspects. It will be appreciated that additional, fewer, different, and/or a different order of steps may be used in some non-limiting embodiments or aspects. In some non-limiting embodiments or aspects, a step may be automatically performed in response to performance and/or completion of a prior step. It should be understood that the steps of process 300 may be performed by one or more processors of one computing device (e.g., a single computing device, etc.) and/or more than one computing devices (e.g., a group of computing devices, etc.) such as one or more processors of central authority 104, one or more client devices 106 of plurality of client devices 106, and/or one or more processors of another computing device. In some non-limiting embodiments or aspects, one or more processors of peer-assisted authoritative network system 102 (e.g., central authority 104 thereof, etc.) may cause one or more processors of a client device of the plurality of client devices 106 to perform one or more steps of process 300 (e.g., via transmitting a message, request, signal, etc.).

As shown in FIG. 3, at step 302, process 300 may include obtaining input associated with an authoritative simulation state from a first client device executing a first simulation instance. For example, peer-assisted authoritative network system 102 may obtain input associated with an authoritative simulation state from a first client device 106-1 executing a first simulation instance 108-1. Peer-assisted authoritative network system 102 may obtain at least one input associated with an authoritative simulation state from a first client device of a plurality of client devices, the first client device executing a first simulation instance. For example, an input being associated with an authoritative state may be used as an input to generate an updated authoritative simulation state.

In some non-limiting embodiments or aspects, peer-assisted authoritative network system 102 provides direct communication between clients in authoritative networks. Peer-assisted authoritative network system 102 enables direct communication without compromising the integrity of client simulations or making clients more vulnerable to fraudulent or delayed transmissions from malicious participants on the network. In some non-limiting embodiments or aspects, peer-assisted authoritative network system 102 employs a central authority 104 for managing and coordinating interactions among clients. Central authority 104 ensures the integrity of simulations and acts as a trusted entity in the network.

In some non-limiting embodiments or aspects, simulation instances 110-1 to 110-n may obtain (e.g., receive, retrieve, pull, etc.) inputs from client devices 106-1 to 106-n respectively. In some non-limiting embodiments or aspects, simulation instances 110-1 to 110-n may process the inputs received from client devices 106-1 to 106-n by executing simulation instances 110-1 to 110-n with the inputs (e.g., with the inputs applied to simulation instances 110-1 to 110-n). In some non-limiting embodiments or aspects, simulation instances 110-1 to 110-n may transmit the inputs to central authority 104 via client devices 106-1 to 106-n and/or a communication network. For example, client devices 106-1 to 106-n may transmit inputs to simulation instances 110-1 to 110-n for processing and then client devices 106-1 to 106-n may transmit the inputs to central authority 104 such that master simulation instance 108-0 may also process the inputs. In some non-limiting embodiments or aspects.

In some non-limiting embodiments or aspects, peer-assisted authoritative network system 102 may receive first inputs from a user of the first client device. In some non-limiting embodiments or aspects, the first client device (e.g., at least one processor of the first client device) may receive first inputs from the user of the first client device. In some non-limiting embodiments or aspects, peer-assisted authoritative network system 102 (e.g., at least one processor of central authority 104 thereof) may detect that the first client device received inputs from the user of the first client device (e.g., by monitoring the inputs to the simulation instance executing on the first client device).

In some non-limiting embodiments or aspects, peer-assisted authoritative network system 102 may transmit the first inputs from the first client device to the second client device at each frame of the simulation. In some non-limiting embodiments or aspects, first client device may transmit the first inputs to the second client at each frame of the simulation.

In some non-limiting embodiments or aspects, peer-assisted authoritative network system 102 may receive second inputs from a user of the second client device. In some non-limiting embodiments or aspects, the second client device (e.g., at least one processor of the second client device) may receive inputs from the user of the second client device. In some non-limiting embodiments or aspects, peer-assisted authoritative network system 102 (e.g., at least one processor of central authority 104 thereof) may detect that the second client device received inputs from the user of the second client device (e.g., by monitoring the inputs to the simulation instance executing on the second client device).

In some non-limiting embodiments or aspects, peer-assisted authoritative network system 102 may transmit the second inputs to the first client device at each frame of a simulation (e.g., each frame of master simulation instance 108-0 executing on central authority 104 and/or the simulation instance executing on the second client device). In some non-limiting embodiments or aspects, the second client device may transmit the second inputs to the first client device at each frame of the simulation. In some non-limiting embodiments or aspects, peer-assisted authoritative network system 102 may cause the second client device to transmit the second inputs to the first client device at each frame of the simulation (e.g., based on a message transmitted to the second client device from central authority 104 where the message triggers the second client device to transmit the second inputs to the first client device).

In some non-limiting embodiments or aspects, peer-assisted authoritative network system 102 executes a master simulation instance comprising a master simulation state corresponding to at least one frame of a plurality of frames of the master simulation instance. For example, peer-assisted authoritative network system 102 executes a master simulation instance 108-0 comprising a master simulation state corresponding to at least one frame of a plurality of frames of the master simulation instance. In such an example, authoritative network system 102 executes a master simulation instance 108-0. The master simulation instance 108-0 may include a master simulation state. The master simulation state may correspond to at least one frame of a plurality of frames of the master simulation instance.

In some non-limiting embodiments or aspects, master simulation instance 108-0 may include a master simulation state that corresponds to a master simulation instance. In some non-limiting embodiments or aspects, the master simulation state may correspond to at least one frame of a plurality of frames of master simulation instance 108-0.

In some non-limiting embodiments or aspects, a simulation and/or simulations may refer to one or more software instructions (e.g., software applications, simulation instructions, and/or the like) that may be executed on a computing device (e.g., central authority 104 and/or each client device of the plurality of client devices 106). In some non-limiting embodiments or aspects, a simulation may include one or more variables (e.g., variables in a software application corresponding to one or more values). The one or more variables may be controlled (e.g., changed, updated, and/or the like) by one or more inputs from one or more computing devices (e.g., a client device). The one or more variables may provide (e.g., correspond to) one or more outputs of the simulation. A simulation may include executing the one or more software instructions over time such that the software instructions are executed for each period of time in a plurality of periods of time in a duration of time. For example, the one or more software instructions may be executed for a period of time including 50 milliseconds in a duration of time. The one or more software instructions are executed each period of time (e.g., 50 milliseconds) of a plurality of periods of time for the duration of time (e.g., the one or more software instructions are executed every 50 milliseconds for a duration of time, such as 1 hour). In this way, a simulation may update the one or more variables every 50 milliseconds based on the one or more inputs and the one or more software instructions that are executed. One or more simulations may execute on each computing device of a plurality of computing devices in a network (e.g., networked simulations), such that each simulation of the one or more simulations may be synchronized with a master simulation executing on a central authority (e.g., a server, central authority 104, and/or the like).

In some non-limiting embodiments or aspects, a frame may refer to a time interval (e.g., frame rate, time step, tick, and/or the like) of a simulation (e.g., a simulation that is being executed) in which the internal steps (e.g., internal instructions, internal code, and/or the like) of the simulation are executed to provide an output from an input (e.g., a single input, a plurality of inputs, and/or the like). In some non-limiting embodiments or aspects, the internal steps of the simulation may be executed exactly one time per frame. For example, a simulation (e.g., a simulation instance) may be executed for a duration of 10 minutes. The simulation may include a frame having a time interval of 0.05 seconds (e.g., 20 Hz frame rate, and/or the like). Thus, over the 10 minutes of execution, the simulation would have executed the internal steps of the simulation 12,000 times (e.g., the simulation code was executed 12,000 times, the execution of the simulation resulted in 12,000 frames, and/or the like). In this way, the simulation may produce outputs each frame, and each frame may include outputs that are the same as a frame previous to a current frame, and/or outputs that are different and or new as the frame previous to the current frame. In some non-limiting embodiments, actions that are said to occur each frame may occur for each frame or a portion of the plurality of frames for a simulation.

In some non-limiting embodiments or aspects, a client device 106 may transmit an encrypted packet. For example, a first client device may transmit an encrypted packet to second client device of the plurality of client devices. The client device 106 has the capability to send a packet of data that has undergone encryption. Encryption involves converting the original data into a format that is not easily readable without the corresponding decryption key.

In some non-limiting embodiments or aspects, the first client device transmits an encrypted packet to a second client device. This is part of the communication or data exchange process within the networked simulation.

In some non-limiting embodiments or aspects, the central authority 104 knows (e.g., expects, has information about, etc.) an encryption key that will be used by a specific client at a specific time for communicating with a specific peer. For example, central authority 104 provides a controlled or managed approach to encryption within the networked simulation system. As an example, a central authority 104 when governing or managing various aspects of the networked simulation system, may enforce rules, make decisions, and coordinate activities within the simulation.

In some non-limiting embodiments or aspects, the central authority 104 has the ability to make decisions that impact the operation of the networked simulation. This may include deciding how inputs are processed, managing communication between clients, and ensuring the overall integrity of the simulation.

In some non-limiting embodiments or aspects, the central authority 104 enforces rules or protocols within the networked simulation. It may define how clients interact, automatically configure client devices 106, handle inputs, synchronize client device states, and/or the like.

In some non-limiting embodiments or aspects, the central authority 104 coordinates (e.g., synchronizes, etc.) the communications of the clients in the simulation. It may facilitate communication between clients, manage the flow of information, and ensure that the simulation progresses in a coherent and controlled manner.

In some non-limiting embodiments or aspects, the central authority 104 has access to and/or control over key management processes. For example, central authority 104 (or another device of the peer-assisted authoritative network system 102) may distribute and schedule encryption keys to be used by client devices 106. For example, central authority 104 may generate and distribute keys as needed for secure communication.

In some non-limiting embodiments or aspects, peer-assisted authoritative network system 102 may provide an encryption key or a piece of information that may be used to encrypt and/or decrypt data. In this case, the central authority 104 retains knowledge of an encryption key and when it is expected to be used by a client device.

In some non-limiting embodiments or aspects, each client is associated with a set of encryption keys, such as a set of specific keys.

In some non-limiting embodiments or aspects, encryption and decryption are time-sensitive. The encryption key is used at a specific time, introducing a dynamic or time-dependent aspect to the encryption process.

In some non-limiting embodiments or aspects, the encryption key is associated with communication between a specific client and a specific peer. Peer-assisted authoritative network system 102 may provide encryption for a particular interaction within the networked simulation, in this way a controlled and secure approach to encryption in the system, where the central authority manages and assigns encryption keys to specific clients at specific times for communication with specific peers. This controlled approach enhances the security and integrity of communication within the networked simulation.

In some non-limiting embodiments or aspects, peer-assisted authoritative network system 102 generates a first transmission time indicating when to transmit the decryption key from the central authority to the second client device of the plurality of client devices.

In some non-limiting embodiments or aspects, peer-assisted authoritative network system 102 provides the first transmission time based on subtracting a first duration from a second transmission time, wherein the first duration is based on a difference between a second duration and a third duration, wherein the first transmission time is determined by:

$$v = t - ( p - l )$$

such that v is equal to the first transmission time, t is equal to the second transmission time, l is equal to the second duration, and p is equal to the third duration, wherein the second duration is based on a transmission duration between the first client device and the second client device, the third duration is based on the delayed processing penalty associated with the second client device.

In some non-limiting embodiments or aspects, the first client device 106-1 may execute a first simulation instance associated with master simulation instance 108-0.

As shown in FIG. 3, at step 304, process 300 may include associating a delayed processing penalty with the first client device of the plurality of client devices. For example, peer-assisted authoritative network system 102 associates a delayed processing penalty with the first client device 106-1 of the plurality of client devices 106. In such an example, peer-assisted authoritative network system 102 associates a delayed processing penalty with the first client device of the plurality of client devices. The delayed processing penalty may provide a minimum acceptable duration that elapses between an initial instance and a subsequent instance. The initial instance may include the instance that the at least one input by the first client device of the plurality of client devices is generated, transmitted, received, communicated, and/or the like.

In some non-limiting embodiments or aspects, these penalties impose a minimum acceptable duration between the initiation of an input by a client and the subsequent time associated with an authoritative simulation state influenced by that input.

In some non-limiting embodiments or aspects, peer-assisted authoritative network system 102 utilizes encrypted peer-to-peer communication between clients. This ensures that data transmitted directly between clients discourages delay of transmissions to the central authority 104 (e.g., due to the resulting increase in processing delay penalties, etc.) or a peer client (e.g., due to an increase in the time it will take to receive a decryption key).

In some non-limiting embodiments or aspects, peer-assisted authoritative network system 102 audits packets (e.g., communications, etc.). For example, peer-assisted authoritative network system 102 audits packets to verify the integrity of data packets received by a client device from another client device, matches a corresponding packet received by the central authority 104 from the other client device, and/or the like. The audit may determine information associated with the content of packets, the transmission of packets exchanged between clients, and/or the like. This helps detect and prevent any tampering or fraudulent activities during data transmission (e.g., detecting a delayed transmission, etc.).

In some non-limiting embodiments or aspects, peer-assisted authoritative network system 102 may provide one or more routing servers as intermediaries between clients or between a client and the central authority. These servers may facilitate communication, by enhancing security and efficiency.

In some non-limiting embodiments or aspects, peer-assisted authoritative network system 102 provides elements such as a central authority in combination with delayed processing penalties, encrypted peer-to-peer communication, and packet auditing to enable secure and direct communication between clients in an authoritative network.

In some non-limiting embodiments or aspects, client device 106 detects one or more network characteristics related to a transmission duration in at least one communication from the first client device to a second client device.

In some non-limiting embodiments or aspects, client device 106 determines from the one or more network characteristics that the at least one communication arrived on time or that the communication from the first client device to the second client device, satisfies a first threshold value of transmission time.

In some non-limiting embodiments or aspects, in response to determining the one or more characteristics satisfy a first threshold value of transmission time, client device 106 initiates a protective measure by terminating a connection between the first client device and the second client device to protect the second client device.

In some non-limiting embodiments or aspects, client device 106 determines the contents of a communication. For example, client device 106 determines the contents in a packet communicated between the first client device and a second client device.

In some non-limiting embodiments or aspects, client device 106 determines that a second variation in the contents of the communication between the first client device and a second client device satisfies a first threshold value of variation in network latency. In such an example, the client device 106 responds by determining that a first variation in packet contents satisfies the first threshold value of variation in the network latency. In some examples, the client device 106 initiates a protective measure by terminating a connection between the first client device and the second client device, to protect the first client device.

In some non-limiting embodiments or aspects, a first client may terminate communication with a second client, such as communications (e.g., packets, messages, etc.) received directly from the second client device. In other examples, first client device may still receive communications from the second client, but may be programmed or configured to discontinue the use of such communications received (e.g., directly, etc.) from the second client, such as, to avoid using such packets to update the first clients simulation state.

In some non-limiting embodiments or aspects, a subsequent instance may be associated with when the authoritative simulation state may be generated. In such an example, the authoritative simulation state is based on the at least one input of the first client device. In such an example, the simulation state, which is considered authoritative (e.g., reliable and accepted as the reference state, etc.), is determined or influenced by the input received from the first client device. In this way, the inputs provided by the first client device contribute to the generation or update of the authoritative simulation state. The actions or changes initiated by the first client device, as represented by its inputs, play a significant role in determining the state of the overall simulation.

This penalty is designed to prevent one or more clients, one or more client devices, and/or the like, from expecting immediate updates to one or more local simulation states following the initiation of an input. In some examples, the PDP aims to introduce a temporal delay, ensuring that the one or more clients (or client devices) provides a specified time for the authoritative simulation state to be updated or influenced by their inputs before expecting changes in their local simulations. By enforcing this delay, the system promotes synchronization and consistency across each of the client devices, preventing or minimizing premature updates that could lead to discrepancies or artifacts in the networked simulation. In some non-limiting embodiments or aspects, the PDP involves associating a specific time duration with each client device, reflecting the minimum acceptable time that should elapse before the authoritative state reflects the impact of the client's input. In this way, the PDP contributes to the overall integrity and coherence (e.g., a consistency or agreement of simulation states among different client devices of the networked simulation, etc.) by regulating the timing of updates across the distributed simulation instances.

As shown in FIG. 3, at step 306, process 300 may include routing the simulation information associated with the authoritative simulation state. For example, peer-assisted authoritative network system 102 routes (e.g., sends, forwards, or transmits a communication, etc.) the simulation information associated with the authoritative simulation state. For example, peer-assisted authoritative network system 102 (e.g., central authority 104 thereof) may route the input received from the first client device 106-1 to each client device of the plurality of client devices 106 based on receiving the input from the first client device. For example, peer-assisted authoritative network system 102 (e.g., central authority 104 thereof) may route the input received from the first client device 106-1 to each other client device (e.g., each client device of the plurality of client devices 106 excluding the first client device 106-1 that may transmit the input to central authority 104) of the plurality of client devices 106. The first client device 106-1 may not receive the input routed from central authority 104 because the first client device 106-1 was the client device of the plurality of client devices 106 that transmitted the input to central authority 104. In some non-limiting embodiments or aspects, each client device may refer to all client devices of the plurality of client devices 106. Alternatively, each client device may refer to all other client devices of the plurality of client devices while excluding the client device that transmitted the inputs to central authority 104 (e.g., in the preceding example, the first client device).

In some non-limiting embodiments or aspects, each client device of the plurality of client devices 106 may execute a simulation instance of a plurality of simulation instances. In some non-limiting embodiments or aspects, each simulation instance of the plurality of simulation instances may include a simulation state. In some non-limiting embodiments or aspects, each simulation instance of the plurality of simulation instances may be associated with master simulation instance 108-0.

In some non-limiting embodiments or aspects, each client device of the plurality of client devices 106 may execute a simulation instance (e.g., a separate instance of a simulation including instructions to execute a simulation) of a plurality of simulation instances. Each simulation instance of the plurality of simulation instances may include a simulation state. In some non-limiting embodiments or aspects, each simulation instance of the plurality of simulation instances may be associated with master simulation instance 108-0. For example, each simulation instance of the plurality of simulation instances may include a separate instance of a simulation including instructions to execute a simulation (e.g., simulation instructions). Master simulation instance 108-0 may include another separate instance of the simulation including instructions to execute the simulation. Each simulation instance of the plurality of simulation instances and master simulation instance 108-0 may include similar (e.g., the same) simulation instructions executing on each client device of the plurality of client devices 106 and executing on the central authority. In this way, each simulation instance of the plurality of the simulation instances may be associated with master simulation instance 108-0.

In some non-limiting embodiments or aspects, master simulation instance 108-0 may include simulation instructions that are identical to the simulation instructions of each simulation instance of the plurality of simulation instances. Alternatively, master simulation instance 108-0 may include more and/or less instructions than each simulation instance of the plurality of simulation instances. In some non-limiting embodiments or aspects, peer-assisted authoritative network system 102 may synchronize (e.g., match up, synchronize the data, synchronize the simulation state) master simulation instance 108-0 and each simulation of the plurality of simulation instances. In some non-limiting embodiments or aspects, master simulation instance 108-0 and each simulation instance of the plurality of simulation instances may share data (e.g., use common data, transmit data to and receive data from one simulation instance to another simulation instance, including master simulation instance 108-0, and/or the like). In such an example, each simulation instance of the plurality of simulation instances executing on each client device of the plurality of client devices 106 may be associated with a master simulation instance 108-0 executing on the central authority.

As shown in FIG. 3, at step 308, process 300 may include updating a simulation instance of the first client device 106-1 with the simulation information. For example, peer-assisted authoritative network system 102 updates a simulation instance of the first client device 106-1 with the simulation information.

In some non-limiting embodiments or aspects, peer-assisted authoritative network system 102 (e.g., central authority 104 thereof) may update the master simulation state of master simulation instance 108-0 to produce an updated master simulation state. In some non-limiting embodiments or aspects, peer-assisted authoritative network system 102 may update the master simulation state based on a first input from the first client device 106-1 of the plurality of client devices 106. In some non-limiting embodiments or aspects, peer-assisted authoritative network system 102 may update the master simulation state of master simulation instance 108-0 based on a duration of a reconciliation window elapsing.

In some non-limiting embodiments or aspects, a typically peer-to-peer (p2p) network architecture known as rollback is converted to utilize peer-assisted authoritative network system 102. In some non-limiting embodiments or aspects, peer-assisted authoritative network system 102 provides a central authority to maintain a master simulation while still allowing direct communication between clients.

In some non-limiting embodiments or aspects, peer-assisted authoritative network system 102 integrates a central authority into a rollback model. For example, a reconciliation window is provided to manage and minimize computation costs. The reconciliation window ensures that only one simulation update is required for each frame, preventing excessive computational demands as the number of clients on the network increases.

In some non-limiting embodiments or aspects, peer-assisted authoritative network system 102 provides a central authority to eliminate the requirement for deterministic clients in a rollback architecture. A typical peer-to-peer implementation of rollback requires deterministic clients. Deterministic clients generate the same output for a given input, but a combined authoritative and peer-to-peer architecture removes this constraint without increasing the latency between clients. Additionally the use of a central authority in a rollback model allows a greater (e.g., maximum, etc.) number of users to participate in the network without compromising the integrity of the simulation.

In some non-limiting embodiments or aspects, peer-assisted authoritative network system 102 maintains the ability for direct communication between clients. Peer-assisted authoritative network system 102 provides direct communication between clients while still having a central authority maintaining a master simulation.

In some non-limiting embodiments or aspects, peer-assisted authoritative network system 102 may involve the use of local input to generate a faux frame or client-side prediction. Peer-assisted authoritative network system 102 generates a faux frame. For example, client devices 106 generate a faux frame by applying a client user's inputs to the client's simulation. For example, applying a client user's inputs in advance of when the inputs would be used by the central authority to update its simulation. This approach can enhance user experience and responsiveness.

Peer-assisted authoritative network system 102 provides a reconciliation window. Wherein a reconciliation window includes a specific application of peer-assisted authoritative network system 102 that improves a rollback network architecture. The reconciliation window removes the need for deterministic clients and enables direct communication between clients.

In some non-limiting embodiments or aspects, peer-assisted authoritative network system 102 may update the master simulation state of master simulation instance 108-0 in response to the duration of the reconciliation window elapsing.

In some non-limiting embodiments or aspects, peer-assisted authoritative network system 102 may update the simulation state of each simulation instance of the plurality of simulation instances. For example, peer-assisted authoritative network system 102 may update the simulation state of each simulation instance of the plurality of simulation instances by transmitting an updated simulation state (e.g., the updated master simulation state, a plurality of updated simulation states, and/or the like) to each client device of the plurality of client devices 106 executing each simulation instance of the plurality of simulation instances. In some non-limiting embodiments or aspects, peer-assisted authoritative network system 102 may update the simulation state of each simulation instance of the plurality of simulation instances based on the updated master simulation state transmitted to each client device of the plurality of client devices 106.

In some non-limiting embodiments or aspects, the first client device 106-1 may execute a first simulation instance associated with a master simulation instance 108-0 after receiving an update of a plurality of simulations executing on a plurality of client devices. For example, peer-assisted authoritative network system 102 (e.g., central authority 104 thereof) may update the simulation state of each simulation instance of the plurality of simulation instances executing on each client device of the plurality of client devices 106 based on the updated master simulation state. In some non-limiting embodiments or aspects, peer-assisted authoritative network system 102 may update the simulation state of each simulation instance of the plurality of simulation instances based on a duration of a reconciliation window elapsing. In some non-limiting embodiments or aspects, peer-assisted authoritative network system 102 may update the simulation state of each simulation instance of the plurality of simulation instances in response to the duration of the reconciliation window elapsing.

The phrase “in response to” may include the same or similar meaning to the phrase “based on.” However, it should be understood that, in some instances, the phrase “in response to” may include a second action and/or event occurring as a direct response to (e.g., in real-time) a first action and/or event. For example, “in response to” may refer to the second action and/or event occurring automatically and immediately after (e.g., within milliseconds, seconds, and/or the like) the first action and/or event in real-time.

In some non-limiting embodiments or aspects, peer-assisted authoritative network system 102 (e.g., central authority 104 thereof) may update the simulation state of each simulation instance of the plurality of simulation instances executing on each client device of the plurality of client devices 106 based on peer-assisted authoritative network system 102 transmitting (e.g., broadcasting) the updated master simulation state to each client device of the plurality of client devices 106 such that each client device of the plurality of client devices 106 may update each simulation instance (e.g., each client device may update the client device's own simulation instance that the client device is executing).

In some non-limiting embodiments or aspects, the duration of the reconciliation window may include a maximum duration of a network latency time of a plurality of network latency times between central authority 104 and each client device of the plurality of client devices 106. In some non-limiting embodiments or aspects, the duration of the reconciliation window may include a predetermined duration of a network latency time that establishes (e.g., represents, corresponds to, includes, and/or the like) a maximum latency time (e.g., of a plurality of latency times) between the central authority and each client device of the plurality of client devices.

In some non-limiting embodiments or aspects, peer-assisted authoritative network system 102 may modify the predetermined duration such that peer-assisted authoritative network system 102 may modify the maximum latency time corresponding to the reconciliation window. For example, each client device of the plurality of client devices 106 may have a network latency time (e.g., each client device's own network latency time) between the client device and the central authority. As a further example, a first client device 106-1 may have a network latency time between the first client device 106-1 and the central authority of 5 milliseconds. A second client device may have a network latency time between the second client device and the central authority of 10 milliseconds. A third client device may have a network latency time between the third client device and the central authority of 15 milliseconds. Peer-assisted authoritative network system 102 may select (e.g., and/or modify) the duration of the reconciliation window is based on a predetermined duration. Peer-assisted authoritative network system 102 may determine the duration of the reconciliation window as 20 milliseconds. In this way, peer-assisted authoritative network system 102 may determine the reconciliation window of 20 milliseconds to establish a maximum latency time of 20 milliseconds between each client device of the plurality of client devices and the central authority.

In some non-limiting embodiments or aspects, peer-assisted authoritative network system 102 may modify the predetermined duration to provide a modified reconciliation window. Peer-assisted authoritative network system 102 may modify the predetermined duration (e.g., the reconciliation window) by selecting (e.g., generating) a new predetermined duration of a network latency time of a plurality of network latency times between central authority 104 and each client device of the plurality of client devices. In some non-limiting embodiments or aspects, peer-assisted authoritative network system 102 may modify the predetermined duration to provide the new predetermined duration based on peer-assisted authoritative network system 102 detecting one or more anomalies (e.g., artifacts, variations in network latency, and/or the like). Peer-assisted authoritative network system 102 may select the predetermined duration from any number of feasible durations and/or network latency times and peer-assisted authoritative network system 102 is not limited to any specific duration and/or network latency time. In this way, the predetermined duration may include a modifiable predetermined duration of a network latency time.

As described, peer-assisted authoritative network system 102 may select and/or modify the reconciliation window to provide a duration of time where the central authority (e.g., central authority 104) may wait until all inputs within the reconciliation window have been received so that the central authority may process all inputs before transmitting updates (e.g., updates to the simulation state and/or the like) to the plurality of client devices. The plurality of client devices may receive the inputs routed from the central authority and may allow the plurality of client devices to process the inputs received based on routing the inputs from the central authority to provide an approximation of a simulation state before the plurality of client devices receives the updates transmitted from the central authority. In turn, the use of the reconciliation window may allow peer-assisted authoritative network system 102 to facilitate a larger number of client devices of the plurality of client devices to participate in executing the simulation (e.g., a simulation instance) without increasing resources.

In some non-limiting embodiments or aspects, peer-assisted authoritative network system 102 communicates via at least one routing. For example, the at least one routing device may transmit one or more intermediary communications between the first client device of the plurality of client devices, a second client device of the plurality of client devices, or a central authority, wherein the first client device, the second client device, or the central authority do not communicate with each other via a direct connection.

In some non-limiting embodiments or aspects, peer-assisted authoritative network system 102 may select an existing network latency time as the reconciliation window. For example, each client device of the plurality of client devices 106 may have a network latency time (e.g., each client device's own network latency time) between the client device and the central authority. As a further example, a first client device 106-1 may have a network latency time between the first client device 106-1 and the central authority of 5 milliseconds. A second client device may have a network latency time between the second client device and the central authority of 10 milliseconds. A third client device may have a network latency time between the third client device and the central authority of 15 milliseconds. Peer-assisted authoritative network system 102 may determine (e.g., and/or modify) the duration of the reconciliation window based on the network latency times (e.g., the plurality of network latency times) of the first client, the second client, and the third client. Peer-assisted authoritative network system 102 may select a greatest duration from the plurality of network latency times to be the duration of the reconciliation window (e.g., in this example, peer-assisted authoritative network system 102 would select 15 milliseconds as the duration of the reconciliation window). Peer-assisted authoritative network system 102 may select a greatest duration of a network latency time of a plurality of network latency times between central authority 104 and each client device of the plurality of client devices 106 from any number of client devices of the plurality of client devices 106 and peer-assisted authoritative network system 102 is not limited to the number of client devices 106 provided in the example described herein.

In some non-limiting embodiments or aspects, network latency and/or network latency time may refer to one-way network latency where appropriate. For example, network latency may refer to network latency of a message transmitted from a client device of the plurality of client devices 106 to central authority 104 (e.g., one-way network latency). Network latency time may refer to a duration of time corresponding to one-way network latency. For example, network latency time may refer to a duration of time that elapses from a first time a client device of the plurality of client devices 106 transmits a message to central authority 104 to a second time central authority 104 receives the message.

In some non-limiting embodiments or aspects, network latency and/or network latency time may refer to roundtrip network latency (e.g., two-way network latency) where appropriate. For example, network latency may refer to network latency of a message transmitted from a client device of the plurality of client devices 106 to central authority 104 and transmitted from central authority 104 back to the client device of the plurality of client devices 106 (e.g., roundtrip network latency). Network latency time may refer to a duration of time corresponding to roundtrip network latency. For example, network latency time may refer to a duration of time that elapses from a first time a client device of the plurality of client devices 106 transmits a message to central authority 104 to a second time the client device of the plurality of client devices 106 receives the message back from central authority 104.

In some non-limiting embodiments or aspects, a reconciliation window may refer to a period of time that may be repeated (e.g., executed repeatedly) by peer-assisted authoritative network system 102 (e.g., central authority 104 thereof). In some non-limiting embodiments or aspects, a reconciliation window may include a period of time when peer-assisted authoritative network system 102 (e.g., central authority 104 thereof) may receive inputs from a plurality of client devices 106, each client device executing a simulation instance (e.g., a plurality of simulation instances) corresponding to master simulation instance 108-0. For example, peer-assisted authoritative network system 102 (e.g., central authority 104 thereof) may receive inputs from a first plurality of client devices within a first reconciliation window. Within the first reconciliation window, peer-assisted authoritative network system 102 (e.g., central authority 104 thereof) may update the master simulation state of master simulation instance 108-0 based on the inputs received from the first plurality of client devices to produce a first updated master simulation state (e.g., an updated master simulation state of master simulation instance 108-0). Peer-assisted authoritative network system 102 (e.g., central authority 104 thereof) may update the master simulation state of master simulation instance 108-0 based on the reconciliation window elapsing. Each subsequent master simulation state may overwrite (e.g., delete and replace, update, and/or the like) a previous master simulation state. For example, a second updated master simulation state may overwrite the first master simulation state. At a time in which the first reconciliation window elapses, peer-assisted authoritative network system 102 (e.g., central authority 104 thereof) may update a simulation state of the simulation instance (e.g., the plurality of simulation instances) executing on each client device of a plurality of client devices 106 (e.g., the first plurality of client devices, the second plurality of client devices, any combination thereof, and/or the like) based on the updated master simulation state (e.g., the latest master simulation state, the most recent master simulation state at the end of the reconciliation window, the last updated master simulation state that peer-assisted authoritative network system 102 produced based on inputs from one or more client devices 106), and/or the like.

In some non-limiting embodiments or aspects, peer-assisted authoritative network system 102 (e.g., central authority 104 thereof) may coordinate and/or manage (e.g., keep track of, control) the reconciliation window.

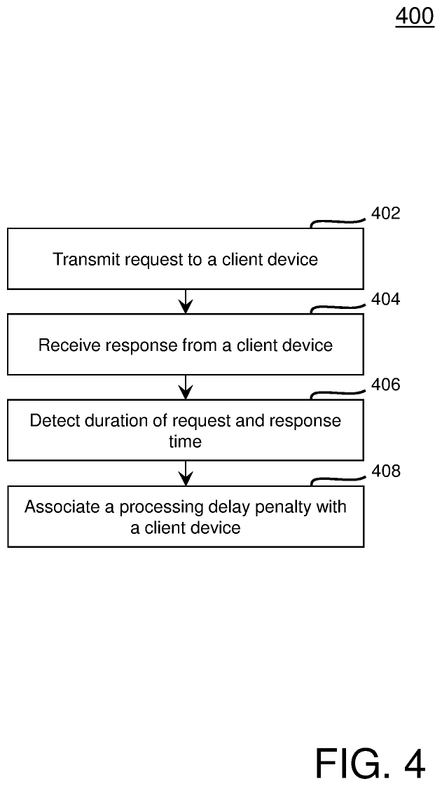

Referring now to FIG. 4, FIG. 4 is a flow diagram of a process 400 for reducing artifacts in networked simulations using a processing delay penalty. The steps shown in FIG. 4 are for example purposes only. It will be appreciated that additional, fewer, different, and/or a different order of steps may be used in some non-limiting embodiments or aspects. In some non-limiting embodiments or aspects, a step may be automatically performed in response to performance and/or completion of a prior step. It should be understood that the steps of process 400 may be performed by one or more processors of one computing device (e.g., a single computing device) and/or more than one computing devices (e.g., a group of computing devices) such as one or more processors of central authority 104, one or more client devices 106 of plurality of client devices 106, and/or one or more processors of another computing device. In some non-limiting embodiments or aspects, one or more processors of peer-assisted authoritative network system 102 (e.g., central authority 104 thereof) may cause one or more processors of a client device of the plurality of client devices 106 to perform one or more steps of process 400 (e.g., via transmitting a message, request, signal, and/or the like).

As shown in FIG. 4, at step 402, process 400 may include transmitting a request to a client device. For example, peer-assisted authoritative network system 102 (e.g., central authority 104 thereof) may transmit a request to each client device of a plurality of client devices 106. In some non-limiting embodiments or aspects, peer-assisted authoritative network system 102 may transmit the request to request a response from each client device of the plurality of client devices 106. In some non-limiting embodiments or aspects, the request transmitted to each client device of the plurality of client devices 106 may request a real-time response from each client device of the plurality of client devices 106. In some non-limiting embodiments or aspects, peer-assisted authoritative network system 102 (e.g., central authority 104 thereof) may transmit a request to each client device of a plurality of client devices 106, requesting a real-time response and/or cause each client device of the plurality of client devices 106 to transmit a real-time response to peer-assisted authoritative network system 102 (e.g., central authority 104 thereof).

As shown in FIG. 4, at step 404, process 400 may include receiving a response from a client device. For example, peer-assisted authoritative network system 102 (e.g., central authority 104 thereof) may receive a response from a client device (e.g., one or more client devices 106 that received the transmitted request from central authority 104) of the plurality of client devices 106 based on the request. As a further example, peer-assisted authoritative network system 102 (e.g., central authority 104 thereof) may receive a real-time response from a client device of the plurality of client devices 106 based on the request.

As shown in FIG. 4, at step 406, process 400 may include detecting a duration of a request and response time. For example, peer-assisted authoritative network system 102 (e.g., central authority 104 thereof) may detect (e.g., measure) a duration (e.g., a transmission duration) for central authority 104 to transmit the request and receive the response to the request. In some non-limiting embodiments or aspects, the duration may be measured from a first time to a second time. In some non-limiting embodiments or aspects, the first time may include a time (e.g., a moment in time, a timestamp) when the request was transmitted from central authority 104 to the client device of the plurality of client devices 106. In some non-limiting embodiments or aspects, a second time may include a time (e.g., a moment in time, a timestamp) when the response was received by central authority 104 from a client device of the plurality of client devices 106 (e.g., any client device of the plurality of client devices 106 that received the request from central authority 104). In some non-limiting embodiments or aspects, peer-assisted authoritative network system 102 may measure a transmission duration for central authority 104. In some non-limiting embodiments or aspects, the transmission duration may be measured from a first time when the request is transmitted from central authority 104 to a second time when the response is received by central authority 104 from a client device (e.g., one or more client devices 106) of the plurality of client devices 106.

In some non-limiting embodiments or aspects, peer-assisted authoritative network system 102 (e.g., central authority 104 thereof) may determine a point value to assign to a client device. For example, peer-assisted authoritative network system 102 may determine a point value (e.g., a point value assignment) to assign to each client device of the plurality of client devices 106 based on the duration (e.g., the transmission duration) for central authority 104 to transmit the request and receive the response to the request (e.g., each client device of the plurality of client devices 106 may be associated with a respective processing delay penalty based on a client device's respective duration of receiving a request from central authority 104 and transmitting a response to central authority 104).

In some non-limiting embodiments or aspects, peer-assisted authoritative network system 102 may determine the processing delay penalty to associate with each client device of the plurality of client devices 106. For example, peer-assisted authoritative network system 102 may determine the processing delay penalty associated with each client device 106 based on the transmission duration. In some non-limiting embodiments or aspects, peer-assisted authoritative network system 102 may associate a processing delay penalty with a client device of the plurality of client devices 106 (e.g., by storing an identifier for each client device of the plurality of client devices 106 in a database and storing a point value assignment for each client device 106 along with the identifier for each client device 106 in the database, associating a client device identifier with a point value assignment).

In some non-limiting embodiments or aspects, peer-assisted authoritative network system 102 may transmit a decryption key for a unique code to the client device of the plurality of client devices 106. In some non-limiting embodiments or aspects, the unique code may include an encrypted unique code. In some non-limiting embodiments or aspects, peer-assisted authoritative network system 102 may transmit the unique code to a second client device of the plurality of client devices 106.

In some non-limiting embodiments or aspects, peer-assisted authoritative network system 102 may generate the second point value based on peer-assisted authoritative network system 102 instructing (e.g., configuring, programming, or otherwise causing) a second client device of the plurality of client devices 106 to transmit a decryption key for a unique code to the client device (e.g., another client device, a first client device, etc.) of the plurality of client devices 106. For example, second client device 106-2 of the plurality of client devices 106 may receive the unique code routed from first client device 106-1 of the plurality of client devices 106. In such an example, peer-assisted authoritative network system 102 may determine a second point value to assign to first client device 106-1 of the plurality of client devices 106 based on the duration of the reconciliation window.

In some non-limiting embodiments or aspects, peer-assisted authoritative network system 102 may generate the second point value based on peer-assisted authoritative network system 102 receiving the unique code routed from the client device of the plurality of client devices 106. In some non-limiting embodiments or aspects, peer-assisted authoritative network system 102 may receive a decrypted unique code routed from a client device of the plurality of client devices 106. In some non-limiting embodiments or aspects, the client device of the plurality of client devices 106 may decrypt the unique code with a decryption key for the unique code. In some non-limiting embodiments or aspects, peer-assisted authoritative network system 102 may generate the second point value based on peer-assisted authoritative network system 102 determining a second point value to assign to the client device of the plurality of client devices 106 based on a duration of a reconciliation window in response to peer-assisted authoritative network system 102 receiving the decrypted unique code from the client device of the plurality of client devices 106.

In some non-limiting embodiments or aspects, peer-assisted authoritative network 102 may receive a verification response from the client device of the plurality of client devices 106 based on peer-assisted authoritative network system 102 transmitting the decryption key for the unique code to the client device of the plurality of client devices 106. In some non-limiting embodiments or aspects, the verification response may include an indication that the client device of the plurality of client devices 106 has received the decryption key for the unique code. In some non-limiting embodiments or aspects, the unique code may be transmitted to the second client device of the plurality of client devices 106 in response to peer-assisted authoritative network system 102 receiving the verification response from the client device of the plurality of client devices 106.

In some non-limiting embodiments or aspects, peer-assisted authoritative network system 102 may generate the third point value based on peer-assisted authoritative network system 102 detecting that the client device of the plurality of client devices 106 received the decryption key for the unique code from a second client device of the plurality of client devices 106. In some non-limiting embodiments or aspects, peer-assisted authoritative network system 102 may generate the third point value based on peer-assisted authoritative network system 102 detecting that the client device of the plurality of client devices 106 received the decryption key for the unique code from the second client device of the plurality of client devices 106 and based on the first duration, a second duration, a third duration, and a fourth duration. In some non-limiting embodiments or aspects, the second duration may be defined by (e.g., equal to) a time elapsed from when central authority 104 transmits the decryption key for the unique code to the second client device to when central authority 104 receives the unique code routed from the client device of the plurality of client devices 106. In some non-limiting embodiments or aspects, the third duration may be defined by a first network latency time between central authority 104 and the second client device of the plurality of client devices 106. In some non-limiting embodiments or aspects, the fourth duration may be defined by a second network latency time between central authority 104 and the client device of the plurality of client devices 106.

In some non-limiting embodiments or aspects, peer-assisted authoritative network system 102 may determine the third point value based on the following equation:

$$u = v - ( w - ( x + y ) )$$

where u is a third duration, v is the first duration, w is the second duration, x is the third duration, and y is the fourth duration.

In some non-limiting embodiments or aspects, peer-assisted authoritative network system 102 may transmit a decryption key for the unique code to the client device of the plurality of client devices 106. In some non-limiting embodiments or aspects, the unique code may include an encrypted unique code.

In some non-limiting embodiments or aspects, peer-assisted authoritative network system 102 may determine the first duration based on a network latency time between central authority 104 and a furthest client device of the plurality of client devices 106, wherein the first duration is defined by (e.g., is equal to) a roundtrip network latency time between central authority 104 and the furthest client device of the plurality of client devices 106.

As shown in FIG. 4, at step 408, process 400 may include associating a processing delay penalty with a client device. For example, peer-assisted authoritative network system 102 may associate a processing delay penalty with a client device. In such an example, (e.g., central authority 104 thereof) peer-assisted authoritative network system 102 may associate a first client device 106-1 of the plurality of client devices 106 with a processing delay penalty.

In some non-limiting embodiments or aspects, a client device (e.g. a first client device 106-1) of the plurality of client devices 106 may initiate communication with another client device (e.g., a second client device) of the plurality of client devices 106. In some non-limiting embodiments or aspects, the client device 106-1 transmits the request (e.g., a request for a connection and/or the like) to a second client device for a connection based on central authority 104 transmitting a message to the first client device 106-1. In some non-limiting embodiments or aspects, first client device 106-1 may transmit the message to the second client device.

In some non-limiting embodiments or aspects, first client device 106-1 may receive second inputs from a user of the second client device. In some non-limiting embodiments or aspects, the second client device (e.g., at least one processor of the second client device) may receive inputs from the user of the second client device. In some non-limiting embodiments or aspects, peer-assisted authoritative network system 102 (e.g., at least one processor of central authority 104 thereof) may detect that the second client device received inputs from the user of the first client device 106-1 (e.g., by monitoring the inputs to the simulation instance executing on the second client device).

In some non-limiting embodiments or aspects, first client device (e.g., 106-1, etc.) may transmit inputs to second client device (e.g., 106-2, etc.) at each frame of a simulation (e.g., each frame of master simulation instance 108-0 executing on central authority 104 and/or the simulation instance executing on the second client device). In some non-limiting embodiments or aspects, the first client device may transmit the first inputs to the second client device at each frame of the simulation.

In some non-limiting embodiments or aspects, the second client may receive first inputs from a user of the first client device. In some non-limiting embodiments or aspects, the first client device may receive second inputs from the user of the second client device. In some non-limiting embodiments or aspects, peer-assisted authoritative network system 102 (e.g., at least one processor of central authority 104 thereof) may detect that the client devices 106 received inputs.

In some non-limiting embodiments or aspects, first client device may transmit the first inputs to the second client device at each frame of the simulation based on the first client device receiving the second inputs from the second client device. In some non-limiting embodiments or aspects, first client device 106-1 transmits the first inputs to the second client device at each frame of the simulation.

In some non-limiting embodiments or aspects, peer-assisted authoritative network system 102 may detect a first variation in transmission characteristics between the first client device and the second client device based on the first client device communicating the first inputs to the second client device at each frame of the simulation. In some non-limiting embodiments or aspects, peer-assisted authoritative network system 102 (e.g., at least one processor thereof) may detect a first variation in network latency between the first client device and the second client device based on the first client device sending the first inputs to the second client device at each frame of the simulation.

In some non-limiting embodiments or aspects, peer-assisted authoritative network system 102 may determine that the first variation in network latency between the first client device and the second client device satisfies a first threshold value of variation in network latency. In some non-limiting embodiments or aspects, peer-assisted authoritative network system 102 (e.g., central authority 104 thereof) may cause the first client device to determine that the first variation in network latency between the first client device and the second client device satisfies a first threshold value of variation in network latency.

In some non-limiting embodiments or aspects, peer-assisted authoritative network system 102 (e.g., central authority 104 thereof) may terminate the connection between the first client device and the second client device. For example, peer-assisted authoritative network system 102 (e.g., central authority 104 thereof) may terminate the connection between the first client device and the second client device in response to determining that the first variation in network latency between the first client device and the second client device satisfies a first threshold value of variation in network latency. In some non-limiting embodiments or aspects, peer-assisted authoritative network system 102 (e.g., central authority 104 thereof) may cause the first client device or the second client device to terminate the connection between the first client device and the second client device.

In some non-limiting embodiments or aspects, peer-assisted authoritative network system 102 may detect (e.g., by causing at least one processor of a first client device or central authority 104 to detect) a second variation in network latency between the first client device and central authority 104 based on receiving inputs from central authority 104. In some non-limiting embodiments or aspects, peer-assisted authoritative network system 102 may determine (e.g., by causing at least one processor of a first client device or central authority 104 to detect) a difference of variation in network latency between the first variation in network latency and the second variation in network latency. In some non-limiting embodiments or aspects, peer-assisted authoritative network system 102 may determine the difference of variation in network latency satisfies a second threshold value of difference of variation in network latency. In some non-limiting embodiments or aspects, peer-assisted authoritative network system 102 may terminate (e.g., by causing at least one processor of a first client device or central authority 104 to terminate) the connection between the first client device and the second client device in response to determining the difference of variation in network latency satisfies the second threshold value.

In some non-limiting embodiments or aspects, peer-assisted authoritative network system 102 (e.g., central authority 104 thereof) may detect a variation in inputs transmitted from the second client device based on the first client device receiving the second inputs from the second client device at each frame of the simulation. In some non-limiting embodiments or aspects, peer-assisted authoritative network system 102 (e.g., central authority 104 thereof) may cause the first client device to detect a variation in inputs transmitted from the second client device based on the first client device receiving the second inputs from the second client device at each frame of the simulation.

In some non-limiting embodiments or aspects, peer-assisted authoritative network system 102 may determine that the variation in inputs satisfies a threshold value of variation in inputs. In some non-limiting embodiments or aspects, peer-assisted authoritative network system 102 may cause the first client device to determine that the variation in inputs satisfies a threshold value of variation in inputs. In some non-limiting embodiments or aspects, in response to peer-assisted authoritative network system 102 and/or the first client device determining that the variation in inputs satisfies the threshold value of variation in inputs, peer-assisted authoritative network system 102 may terminate the connection between the first client device and the second client device. In some non-limiting embodiments or aspects, in response to peer-assisted authoritative network system 102 and/or the first client device determining that the variation in inputs satisfies the threshold value of variation in inputs, peer-assisted authoritative network system 102 may cause the first client device to terminate the connection between the first client device and the second client device.

In some non-limiting embodiments or aspects, peer-assisted authoritative network system 102 (e.g., central authority 104 thereof) may transmit a request to each client device of the plurality of client devices 106. In some non-limiting embodiments or aspects, the request may request a response and determine a network latency based on one or more transmission characteristics associated with each client device of the plurality of client devices 106. In some non-limiting embodiments or aspects, peer-assisted authoritative network system 102 may receive a response from each client device of the plurality of client devices 106. In some non-limiting embodiments or aspects, the response may include the network latency time of each client device of the plurality of client devices 106.

In some non-limiting embodiments or aspects, peer-assisted authoritative network system 102 (e.g., central authority 104 thereof) may transmit a request to each client device of the plurality of client devices. In some non-limiting embodiments or aspects, the request may cause each client device of the plurality of client devices to transmit a message to at least one routing server. In some non-limiting embodiments or aspects, peer-assisted authoritative network system 102 may receive a response from each client device of the plurality of client devices. In some non-limiting embodiments or aspects, the response may include a routed network latency time based on each client device of the plurality of client devices transmitting the message to the at least one routing server. A routed network latency time may refer to a network latency time between a client device of the plurality of client devices and the at least one routing server.

In some non-limiting embodiments or aspects, peer-assisted authoritative network system 102 may determine, based on the routed network latency time, that at least one first client device 106-1 of the plurality of client devices 106 may transmit inputs to at least one second client device of the plurality of client devices 106 via the at least one routing server. In some non-limiting embodiments or aspects, the at least one routing server may be configured to route the inputs transmitted from the at least one first client device 106-1 to the at least one second client device. In some non-limiting embodiments or aspects, the at least one routing server may include a server that includes (e.g., acts, is, performs, and/or the like) as an intermediary server between the at least one first client device 106-1 and the at least one second client device of the plurality of client devices 106.

In some non-limiting embodiments or aspects, the at least one routing server may include an intermediary server between at least one first client device 106-1 of the plurality of client devices 106 and at least one second client device of the plurality of client devices 106 such that the at least one first client device 106-1 of the plurality of client devices 106 and the at least one second client device of the plurality of client devices 106 may communicate via the at least one routing server (e.g., all messages from the at least one first client device 106-1 to the at least one second client device and all messages from the at least one second client device to the at least one first client device 106-1 are transmitted to the at least one routing server before the messages may be transmitted to the at least one client device receiving the messages) and do not communicate via a direct connection.

In some non-limiting embodiments or aspects, peer-assisted authoritative network system 102 (e.g., central authority 104 thereof) may determine that the at least one first client device 106-1 of the plurality of client devices 106 may transmit inputs to the at least one routing server based on the routed network latency time by determining that the at least one first client device 106-1 includes (e.g., has) a lower routed network latency time. For example, the lower routed network latency time may include a shorter amount of time than a network latency time between the at least one first client device 106-1 (and/or another client device) and central authority 104.

In some non-limiting embodiments or aspects, peer-assisted authoritative network system 102 (e.g., central authority 104 thereof) may transmit the inputs, the simulation state updates, a unique code, and/or the requests to the at least one routing server. In some non-limiting embodiments or aspects, peer-assisted authoritative network system 102 (e.g., central authority 104 thereof) may receive the inputs, the unique code, and/or the responses from the at least one routing server (e.g., of a plurality of routing servers) when communicating with each client device of the plurality of client devices 106.

In some non-limiting embodiments or aspects, peer-assisted authoritative network system 102 and/or one or more client devices of the plurality of client devices 106 may transmit the inputs, the simulation state updates, the unique code, and/or the requests to the at least one routing server. In some non-limiting embodiments or aspects, peer-assisted authoritative network system 102 and or one or more client devices of the plurality of client devices 106 may receive the inputs, the unique code, and/or the responses from the at least one routing server (e.g., of a plurality of routing servers) when communicating with one or more other client devices of the plurality of client devices 106.

In some non-limiting embodiments or aspects, the method can be used with reconciliation (i.e., rollback, lag compensation).

In some non-limiting embodiments or aspects, data may include user generated input and simulation state information.

In some non-limiting embodiments or aspects, the inputs from the first client device 106-1 are sent to some, but not all, of the other client devices.

In some non-limiting embodiments or aspects, the central authority 104 updating a client simulation refers to the central authority 104 transmitting simulation information to the client device 106, that the client device 106 uses to update the simulation state of the client device's 106 simulation instance.

In some non-limiting embodiments or aspects, the duration of the reconciliation window may be a predetermined or modifiable duration.

In some non-limiting embodiments or aspects, the client devices may also check the transmission characteristics of communications received from an other client device against the transmission characteristics of a communication received from the central authority 104 to make sure the transmissions characteristics are within acceptable thresholds. In such an example, the client device 106 may terminate communication with the other client device 106 based upon such transmission characteristics satisfying (or failing to satisfy) the acceptable thresholds.

In some non-limiting embodiments, inputs may be user-generated inputs or information based upon a client's simulation state.

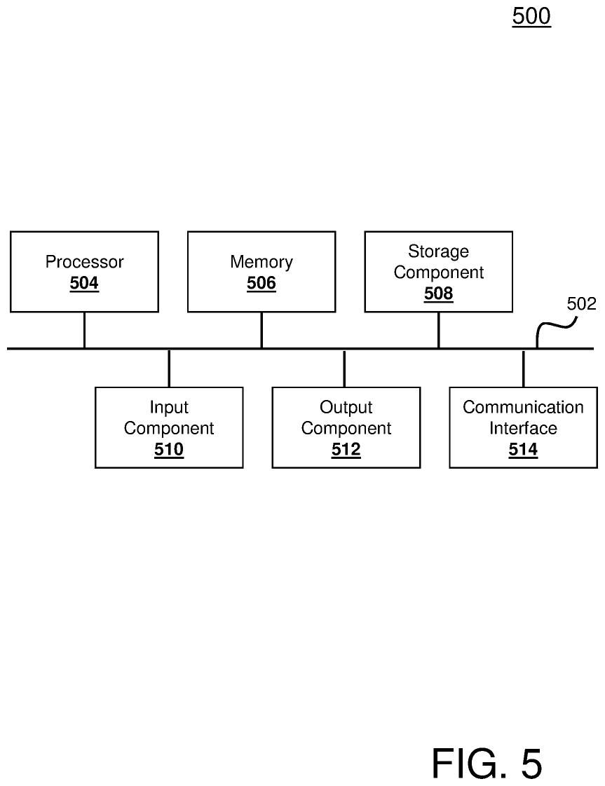

Referring now to FIG. 5, shown is a diagram of example components of a device 500 according to non-limiting embodiments or aspects. Device 500 may correspond to at least one of peer-assisted authoritative network system 102, central authority 104, and/or client device 106 in FIG. 1 and/or at least one of peer-assisted authoritative network system 202, routing server 204, and/or client device 206 in FIG. 2, as an example. In some non-limiting embodiments or aspects, such systems or devices in FIG. 1 or FIG. 2 may include at least one device 500 and/or at least one component of device 500. The number and arrangement of components shown in FIG. 5 are provided as an example. In some non-limiting embodiments or aspects, device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

As shown in FIG. 5, device 500 may include bus 502, processor 504, memory 506, storage component 508, input component 510, output component 512, and communication interface 514. Bus 502 may include a component that permits communication among the components of device 500. In some non-limiting embodiments or aspects, processor 504 may be implemented in hardware, software, or a combination of hardware and software. For example, processor 504 may include a processor (e.g., a central processing unit (CPU), a graphics processing unit (GPU), an accelerated processing unit (APU), etc.), a microprocessor, a digital signal processor (DSP), and/or any processing component (e.g., a field-programmable gate array (FPGA), an application-specific integrated circuit (ASIC), etc.) that can be programmed to perform a function. In some non-limiting embodiments or aspects, processor 504 may be the same as, similar to, and/or included in (e.g., part of) central authority 104. Memory 506 may include random access memory (RAM), read only memory (ROM), and/or another type of dynamic or static storage device (e.g., flash memory, magnetic memory, optical memory, etc.) that stores information and/or instructions for use by processor 504.

With continued reference to FIG. 5, storage component 508 may store information and/or software related to the operation and use of device 500. For example, storage component 508 may include a hard disk (e.g., a magnetic disk, an optical disk, a magneto-optic disk, a solid state disk, etc.) and/or another type of computer-readable medium. Input component 510 may include a component that permits device 500 to receive information, such as via user input (e.g., a touch screen display, a keyboard, a keypad, a mouse, a button, a switch, a microphone, etc.). Additionally, or alternatively, input component 510 may include a sensor for sensing information (e.g., a global positioning system (GPS) component, an accelerometer, a gyroscope, an actuator, etc.). Output component 512 may include a component that provides output information from device 500 (e.g., a display, a speaker, one or more light-emitting diodes (LEDs), etc.). Communication interface 514 may include a transceiver-like component (e.g., a transceiver, a separate receiver and transmitter, etc.) that enables device 500 to communicate with other devices, such as via a wired connection, a wireless connection, or a combination of wired and wireless connections. Communication interface 514 may permit device 500 to receive information from another device and/or provide information to another device. For example, communication interface 514 may include an Ethernet interface, an optical interface, a coaxial interface, an infrared interface, a radio frequency (RF) interface, a universal serial bus (USB) interface, a Wi-Fi® interface, a cellular network interface, and/or the like.

Device 500 may perform one or more processes described herein. Device 500 may perform these processes based on processor 504 executing software instructions stored by a computer-readable medium, such as memory 506 and/or storage component 508. A computer-readable medium may include any non-transitory memory device. A memory device includes memory space located inside of a single physical storage device or memory space spread across multiple physical storage devices. Software instructions may be read into memory 506 and/or storage component 508 from another computer-readable medium or from another device via communication interface 514. When executed, software instructions stored in memory 506 and/or storage component 508 may cause processor 504 to perform one or more processes described herein. Additionally, or alternatively, hardwired circuitry may be used in place of or in combination with software instructions to perform one or more processes described herein. Thus, embodiments described herein are not limited to any specific combination of hardware circuitry and software. The term “programmed or configured,” as used herein, refers to an arrangement of software, hardware circuitry, or any combination thereof on one or more devices.

Although embodiments have been described in detail for the purpose of illustration, it is to be understood that such detail is solely for that purpose and that the disclosure is not limited to the disclosed embodiments or aspects, but, on the contrary, is intended to cover modifications and equivalent arrangements that are within the spirit and scope of the appended claims. For example, it is to be understood that the present disclosure contemplates that, to the extent possible, one or more features of any embodiment or aspect can be combined with one or more features of any other embodiment or aspect.

What is claimed is:

1. A computer-implemented method for reducing artifacts in a networked simulation, comprising:
obtaining, with the at least one processor, at least one input associated with an authoritative simulation state from a first client device of a plurality of client devices, the first client device executing a first simulation instance;
associating, with the at least one processor, a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and
routing, with the at least one processor, simulation information to the plurality of client devices, the simulation information associated with the authoritative simulation state, wherein one or more simulation instances of the first client device of the plurality of client devices are updated with the simulation information.

2. The computer-implemented method of claim 1, further comprising:
communicating via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

3. The computer-implemented method of claim 1, further comprising:
updating a simulation state of the first simulation instance of the one or more simulation instances based on the simulation information routed by the central authority to each client device of the plurality of client devices; or
updating the simulation state based on the at least one input transmitted by at least one of the client devices to an other client device of the plurality of client devices.

4. The computer-implemented method of claim 1, further comprising:
communicating the simulation information by a central authority to at least one client device of the plurality of client devices based on the at least one input received by the central authority from at least one other client device of the plurality of client devices.

5. The computer-implemented method of claim 1, further comprising:
executing a master simulation instance, the master simulation instance comprising a master simulation state, wherein the master simulation state provides a source of the authoritative simulation state, the authoritative simulation state comprising at least a subset of the master simulation state.

6. The computer-implemented method of claim 5, further comprising:
providing a reconciliation window, the reconciliation window including a duration of a network latency time that establishes a maximum latency time between the central authority and at least one client device of the plurality of client devices; and
periodically updating the master simulation state of the master simulation instance based on a duration of the reconciliation window elapsing.

7. The computer-implemented method of claim 1, further comprising:
detecting one or more transmission characteristics related to a transmission duration in at least one communication from the first client device to a second client device;
determining from the one or more transmission characteristics that the at least one communication arrived on time or that the communication from the first client device to the second client device satisfies a first threshold value of transmission time; and
in response to determining the one or more transmission characteristics satisfies a first threshold value of transmission time, initiating a protective measure by terminating a connection between the first client device and the second client device.

8. The computer-implemented method of claim 1, further comprising:
detecting contents of a communication between the first client device and a second client device;
determining a variation in the contents of the communication between the first client device and a second client device satisfies a first threshold value of variation in the contents; and
in response to determining that a variation in contents satisfies the first threshold value of variation in the contents, initiating a protective measure by terminating a connection between the first client device and the second client device.

9. The computer-implemented method of claim 1, wherein a central authority is configured to transmit a decryption key to the second client device, and further comprising:
transmitting, by the first client device, an encrypted packet to the second client device of the plurality of client devices;
transmitting a corresponding decryption key to the second client device, wherein the decryption key is sent by a client device of the plurality of client devices or the central authority; and
generating a first transmission time indicating when to transmit the decryption key from the central authority to the second client device of the plurality of client devices, the first transmission time based on subtracting a first duration from a second transmission time, wherein the first duration is based on a difference between a second duration and a third duration, wherein
the first transmission time is determined by:
$$v = t - ( p - l )$$
such that v is equal to the first transmission time, t is equal to the second transmission time, l is equal to the second duration, and p is equal to the third duration, wherein the second duration is based on one or more transmission characteristics between the first client device and the second client device, and the third duration is based on the delayed processing penalty associated with the second client device.

10. The computer-implemented method of claim 9, wherein the second transmission time is based on a time the first client device transmits the encrypted packet to the second client device; and
the central authority knows an encryption key that will be used by a specific client at a specific time for communicating with a specific peer.

11. A system, comprising:
a memory; and
at least one processor coupled to the memory and configured to:
obtain at least one input associated with an authoritative simulation state from a first client device of a plurality of client devices, the first client device executing a first simulation instance;
associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and
route simulation information to the plurality of client devices, the simulation information associated with the authoritative simulation state, wherein one or more simulation instances of the first client device of the plurality of client devices are updated with the simulation information.

12. The system of claim 11, wherein the at least one processor is further configured to:
communicate via at least one routing device, wherein the at least one routing device transmits one or more intermediary communications between the first client device of the plurality of client devices, a second client device of the plurality of client devices, or a central authority, wherein the first client device, the second client device, or the central authority do not communicate with each other via a direct connection.

13. The system of claim 11, wherein the at least one processor is further configured to:
update a simulation state of the first simulation instance of the one or more simulation instances based on the simulation information routed by the central authority to each client device of the plurality of client devices; or
update the simulation state based on the at least one input transmitted by at least one of the client devices to another client device of the plurality of client devices.

14. The system of claim 11, wherein the at least one processor is further configured to:
communicate the simulation information by a central authority to at least one client device of the plurality of client devices based on the at least one input received by the central authority from at least one other client device of the plurality of client devices.

15. The system of claim 11, wherein the at least one processor is further configured to:
execute a master simulation instance, the master simulation instance comprising a master simulation state, wherein the master simulation state provides a source of the authoritative simulation state, the authoritative simulation state comprising at least a subset of the master simulation state.

16. The system of claim 15, wherein the at least one processor is further configured to:
provide a reconciliation window, the reconciliation window including a duration of a network latency time that establishes a maximum latency time between the central authority and at least one client device of the plurality of client devices; and
periodically update the master simulation state of the master simulation instance based on the duration of the reconciliation window elapsing.

17. The system of claim 11, wherein the at least one processor is further configured to:
detect contents of a communication between the first client device and a second client device;
determine a variation in the contents of the communication between the first client device and a second client device satisfies a first threshold value of variation in the contents; and
in response to determining that a variation in contents satisfies the first threshold value of variation in the contents, initiate a protective measure by terminating a connection between the first client device and the second client device.

18. The system of claim 11, wherein the at least one processor is further configured to:
determine contents of a communication between the first client device and a second client device;
determine a second variation in the contents of the communication between the first client device and the second client device, satisfies a first threshold value of variation in a network latency; and
in response to determining that a first variation in packet contents satisfies the first threshold value of variation in the network latency, initiate a protective measure by terminating a connection between the first client device and the second client device.

19. The system of claim 11, wherein a central authority is configured to transmit a decryption key to the second client device, and the at least one processor is further configured to:
transmit an encrypted packet to the second client device of the plurality of client devices;
transmit a corresponding decryption key to the second client device, wherein the decryption key is sent by a client device of the plurality of client devices or the central authority; and
generate a first transmission time indicating when to transmit the decryption key from the central authority to the second client device of the plurality of client devices, the first transmission time based on subtracting a first duration from a second transmission time, wherein the first duration is based on a difference between a second duration from a third duration, wherein
the first transmission time is determined by:
$$v = t - ( p - l )$$
such that v is equal to the first transmission time, t is equal to the second transmission time, l is equal to the second duration, and p is equal to the third duration, wherein the second duration is based on one or more transmission characteristics between the first client device and the second client device, the third duration is based on the delayed processing penalty associated with the second client device.

20. A non-transitory computer-readable medium having instructions stored thereon that, when executed by at least one computing device, cause the at least one computing device to:
obtain at least one input associated with an authoritative simulation state from a first client device of a plurality of client devices, the first client device executing a first simulation instance;
associate a delayed processing penalty with the first client device of the plurality of client devices, the delayed processing penalty providing a minimum acceptable duration that elapses between an initial instance associated with the at least one input by the first client device of the plurality of client devices and a subsequent instance that is associated with generating the authoritative simulation state based on the at least one input of the first client device; and
route simulation information to the plurality of client devices, the simulation information associated with the authoritative simulation state, wherein one or more simulation instances of the first client device of the plurality of client devices are updated with the simulation information.
